(19) United States
(12) Patent Application Publication
(10) Pub. No.: US 2018/0113747 A1
(43) Pub. Date: Apr. 26, 2018

(54) OVERDRIVE MODE FOR DISTRIBUTED STORAGE NETWORKS

(71) Applicant: International Business Machines Corporation, Armonk, NY (US)

(72) Inventors: Jason K. Resch, Chicago, IL (US); Wesley B. Leggette, Chicago, IL (US); Ravi V. Khadiwala, Bartlett, IL (US); Randy Dean Pfeifer, Warrenville, IL (US); Bruno Hennig Cabral, Chicago, IL (US); Ilya Volvovski, Chicago, IL (US); Joseph M. Kaczmarek, Chicago, IL (US)

(21) Appl. No.: 15/848,137

(22) Filed: Dec. 20, 2017

Related U.S. Application Data
(63) Continuation-in-part of application No. 14/847,855, filed on Sep. 8, 2015, now Pat. No. 9,916,114.
(60) Provisional application No. 62/072,123, filed on Oct. 29, 2014.

(51) Int. Cl. G06F 9/50; H04L 29/08; G06F 11/10

(52) U.S. Cl. CPC G06F 9/5072; H03M 13/1515; G06F 11/1004; H04L 67/1097

(57) ABSTRACT

A method for implementing an overdrive in a dispersed storage network begins by a processing module receiving an access request for a set of encoded data slices and continues with the processing module determining whether a level of access requests for the DSN meets a predetermined threshold. When the level of access requests for the DSN meets the predetermined threshold, the method continues with the processing module transitioning from a first operational mode to a second operational mode. The method continues with the processing module determining whether the level of access requests for the DSN is below the predetermined threshold, and when it is, transitioning back to the first operational mode.

### CROSS REFERENCE TO RELATED PATENTS

The present U.S. Utility patent application claims priority pursuant to 35 U.S.C. § 120 as a continuation-in-part of U.S. Utility application Ser. No. 14/847,855, entitled “DETERMINISTICALLY SHARING A PLURALITY OF PROCESSING RESOURCES”, filed Sep. 8, 2015, which claims priority pursuant to 35 U.S.C. § 119(e) to U.S. Provisional Application No. 62/072,123, entitled “ASSIGNING TASK EXECUTION RESOURCES IN A DISPERSED STORAGE NETWORK,” filed Oct. 29, 2014, both of which are hereby incorporated herein by reference in their entirety and made part of the present U.S. Utility patent application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

### Technical Field of the Invention

This invention relates generally to computer networks and more particularly to dispersed storage of data and distributed task processing of data.

### Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc., on an Internet storage system. The Internet storage system may include a RAID (redundant array of independent disks) system and/or a dispersed storage system that uses an error correction scheme to encode data for storage.

### BRIEF DESCRIPTION OF THE SEVERAL VIEWS OF THE DRAWING(S)

FIG. 1 is a schematic block diagram of an embodiment of a distributed computing system in accordance with the present invention;

FIG. 2 is a schematic block diagram of an embodiment of a computing core in accordance with the present invention;

FIG. 3 is a diagram of an example of a distributed storage and task processing in accordance with the present invention;

FIG. 4 is a schematic block diagram of an embodiment of an outbound distributed storage and/or task (DST) processing in accordance with the present invention;

FIG. 5 is a logic diagram of an example of a method for outbound DST processing in accordance with the present invention;

FIG. 6 is a schematic block diagram of an embodiment of a dispersed error encoding in accordance with the present invention;

FIG. 7 is a diagram of an example of a segment processing of the dispersed error encoding in accordance with the present invention;

FIG. 8 is a diagram of an example of error encoding and slicing processing of the dispersed error encoding in accordance with the present invention;

FIG. 9A is a schematic block diagram of another embodiment of a dispersed storage network (DSN) in accordance with the present invention;

FIG. 9B is a flowchart illustrating an example of storing data in accordance with the present invention;

FIG. 10A is a schematic block diagram of another embodiment of a dispersed storage network (DSN) in accordance with the present invention;

FIG. 10B is a flowchart illustrating an example of migrating stored data in accordance with the present invention;

FIG. 11A is a schematic block diagram of another embodiment of a dispersed storage network (DSN) in accordance with the present invention;

FIG. 11B is a flowchart illustrating another example of storing data in accordance with the present invention;

FIG. 12A is a schematic block diagram of another embodiment of a dispersed storage network (DSN) in accordance with the present invention;

FIG. 12B is a flowchart illustrating an example of rebuilding stored data in accordance with the present invention;

FIG. 13A is a schematic block diagram of another embodiment of a dispersed storage network (DSN) in accordance with the present invention;

FIG. 13B is a flowchart illustrating another example of storing data in accordance with the present invention;

FIG. 14A is a state transition diagram of modes of operation of a dispersed storage network (DSN) in accordance with the present invention;

FIG. 14B is a flowchart illustrating an example of determining a mode of operation of a dispersed storage network (DSN) in accordance with the present invention;

FIG. 15A is a schematic block diagram of another embodiment of a dispersed storage network (DSN) in accordance with the present invention;

FIG. 15B is a flowchart illustrating an example of accessing data in a dispersed storage network (DSN) in accordance with the present invention;

FIG. 16A is a schematic block diagram of another embodiment of a dispersed storage network (DSN) in accordance with the present invention; and

FIG. 16B is a flowchart illustrating another example of storing data in accordance with the present invention.

### DETAILED DESCRIPTION OF THE INVENTION

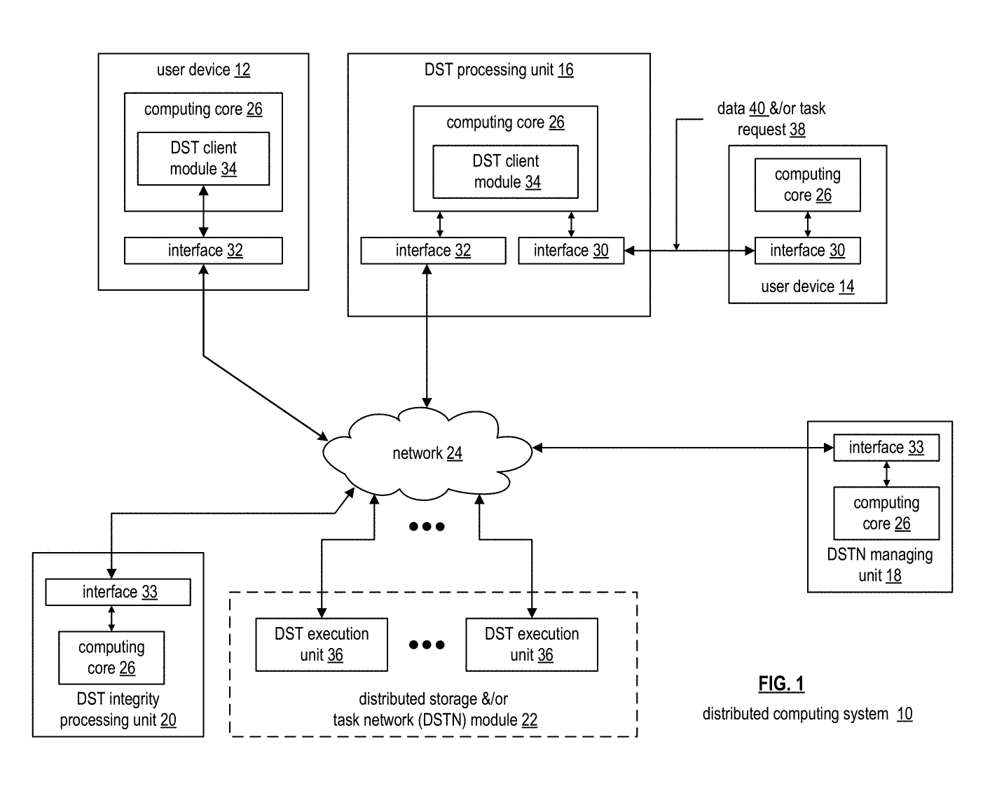

FIG. 1 is a schematic block diagram of an embodiment of a distributed computing system 10 that includes a user device 12 and/or a user device 14, a distributed storage and/or task (DST) processing unit 16, a distributed storage and/or task network (DSTN) managing unit 18, a DST integrity processing unit 20, and a distributed storage and/or task network (DSTN) module 22. The components of the distributed computing system 10 are coupled via a network 24, which may include one or more wireless and/or wire lined communication systems; one or more private intranet systems and/or public internet systems; and/or one or more local area networks (LAN) and/or wide area networks (WAN).

The DSTN module 22 includes a plurality of distributed storage and/or task (DST) execution units 36 that may be located at geographically different sites (e.g., one in Chicago, one in Milwaukee, etc.). Each of the DST execution units is operable to store dispersed error encoded data and/or to execute, in a distributed manner, one or more tasks on data. The tasks may be a simple function (e.g., a mathematical function, a logic function, an identify function, a find function, a search engine function, a replace function, etc.), a complex function (e.g., compression, human and/or computer language translation, text-to-voice conversion, voice-to-text conversion, etc.), multiple simple and/or complex functions, one or more algorithms, one or more applications, etc.

Each of the user devices 12-14, the DST processing unit 16, the DSTN managing unit 18, and the DST integrity processing unit 20 include a computing core 26 and may be a portable computing device and/or a fixed computing device. A portable computing device may be a social networking device, a gaming device, a cell phone, a smart phone, a personal digital assistant, a digital music player, a digital video player, a laptop computer, a handheld computer, a tablet, a video game controller, and/or any other portable device that includes a computing core. A fixed computing device may be a personal computer (PC), a computer server, a cable set-top box, a satellite receiver, a television set, a printer, a fax machine, home entertainment equipment, a video game console, and/or any type of home or office computing equipment. User device 12 and DST processing unit 16 are configured to include a DST client module 34.

With respect to interfaces, each interface 30, 32, and 33 includes software and/or hardware to support one or more communication links via the network 24 indirectly and/or directly. For example, interface 30 supports a communication link (e.g., wired, wireless, direct, via a LAN, via the network 24, etc.) between user device 14 and the DST processing unit 16. As another example, interface 32 supports communication links (e.g., a wired connection, a wireless connection, a LAN connection, and/or any other type of connection to/from the network 24) between user device 12 and the DSTN module 22 and between the DST processing unit 16 and the DSTN module 22. As yet another example, interface 33 supports a communication link for each of the DSTN managing unit 18 and DST integrity processing unit 20 to the network 24.

The distributed computing system 10 is operable to support dispersed storage (DS) error encoded data storage and retrieval, to support distributed task processing on received data, and/or to support distributed task processing on stored data. In general and with respect to DS error encoded data storage and retrieval, the distributed computing system 10 supports three primary operations: storage management, data storage and retrieval and data storage integrity verification. In accordance with these three primary functions, data can be encoded, distributedly stored in physically different locations, and subsequently retrieved in a reliable and secure manner. Such a system is tolerant of a significant number of failures (e.g., up to a failure level, which may be greater than or equal to a pillar width minus a decode threshold minus one) that may result from individual storage device failures and/or network equipment failures without loss of data and without the need for a redundant or backup copy. Further, the system allows the data to be stored for an indefinite period of time without data loss and does so in a secure manner (e.g., the system is very resistant to attempts at hacking the data).

The second primary function (i.e., distributed data storage and retrieval) begins and ends with a user device 12-14. For instance, if a second type of user device 14 has data 40 to store in the DSTN module 22, it sends the data 40 to the DST processing unit 16 via its interface 30. The interface 30 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). In addition, the interface 30 may attach a user identification code (ID) to the data 40.

To support storage management, the DSTN managing unit 18 performs DS management services. One such DS management service includes the DSTN managing unit 18 establishing distributed data storage parameters (e.g., vault creation, distributed storage parameters, security parameters, billing information, user profile information, etc.) for a user device 12-14 individually or as part of a group of user devices. For example, the DSTN managing unit 18 coordinates creation of a vault (e.g., a virtual memory block) within memory of the DSTN module 22 for a user device, a group of devices, or for public access and establishes per vault dispersed storage (DS) error encoding parameters for a vault. The DSTN managing unit 18 may facilitate storage of DS error encoding parameters for each vault of a plurality of vaults by updating registry information for the distributed computing system 10. The facilitating includes storing updated registry information in one or more of the DSTN module 22, the user device 12, the DST processing unit 16, and the DST integrity processing unit 20.

The DS error encoding parameters (e.g., or dispersed storage error coding parameters) include data segmenting information (e.g., how many segments data (e.g., a file, a group of files, a data block, etc.) is divided into), segment security information (e.g., per segment encryption, compression, integrity checksum, etc.), error coding information (e.g., pillar width, decode threshold, read threshold, write threshold, etc.), slicing information (e.g., the number of encoded data slices that will be created for each data segment); and slice security information (e.g., per encoded data slice encryption, compression, integrity checksum, etc.).

The DSTN managing unit 18 creates and stores user profile information (e.g., an access control list (ACL)) in local memory and/or within memory of the DSTN module 22. The user profile information includes authentication information, permissions, and/or the security parameters. The security parameters may include encryption/decryption scheme, one or more encryption keys, key generation scheme, and/or data encoding/decoding scheme.

The DSTN managing unit 18 creates billing information for a particular user, a user group, a vault access, public vault access, etc. For instance, the DSTN managing unit 18 tracks the number of times a user accesses a private vault and/or public vaults, which can be used to generate a per-access billing information. In another instance, the DSTN managing unit 18 tracks the amount of data stored and/or retrieved by a user device and/or a user group, which can be used to generate a per-data-amount billing information.

Another DS management service includes the DSTN managing unit 18 performing network operations, network administration, and/or network maintenance. Network operations includes authenticating user data allocation requests (e.g., read and/or write requests), managing creation of vaults, establishing authentication credentials for user devices, adding/deleting components (e.g., user devices, DST execution units, and/or DST processing units) from the distributed computing system 10, and/or establishing authentication credentials for DST execution units 36. Network administration includes monitoring devices and/or units for failures, maintaining vault information, determining device and/or unit activation status, determining device and/or unit loading, and/or determining any other system level operation that affects the performance level of the system 10. Network maintenance includes facilitating replacing, upgrading, repairing, and/or expanding a device and/or unit of the system 10.

To support data storage integrity verification within the distributed computing system 10, the DST integrity processing unit 20 performs rebuilding of ‘bad’ or missing encoded data slices. At a high level, the DST integrity processing unit 20 performs rebuilding by periodically attempting to retrieve/list encoded data slices, and/or slice names of the encoded data slices, from the DSTN module 22. For retrieved encoded slices, they are checked for errors due to data corruption, outdated version, etc. If a slice includes an error, it is flagged as a ‘bad’ slice. For encoded data slices that were not received and/or not listed, they are flagged as missing slices. Bad and/or missing slices are subsequently rebuilt using other retrieved encoded data slices that are deemed to be good slices to produce rebuilt slices. The rebuilt slices are stored in memory of the DSTN module 22. Note that the DST integrity processing unit 20 may be a separate unit as shown, it may be included in the DSTN module 22, it may be included in the DST processing unit 16, and/or distributed among the DST execution units 36.

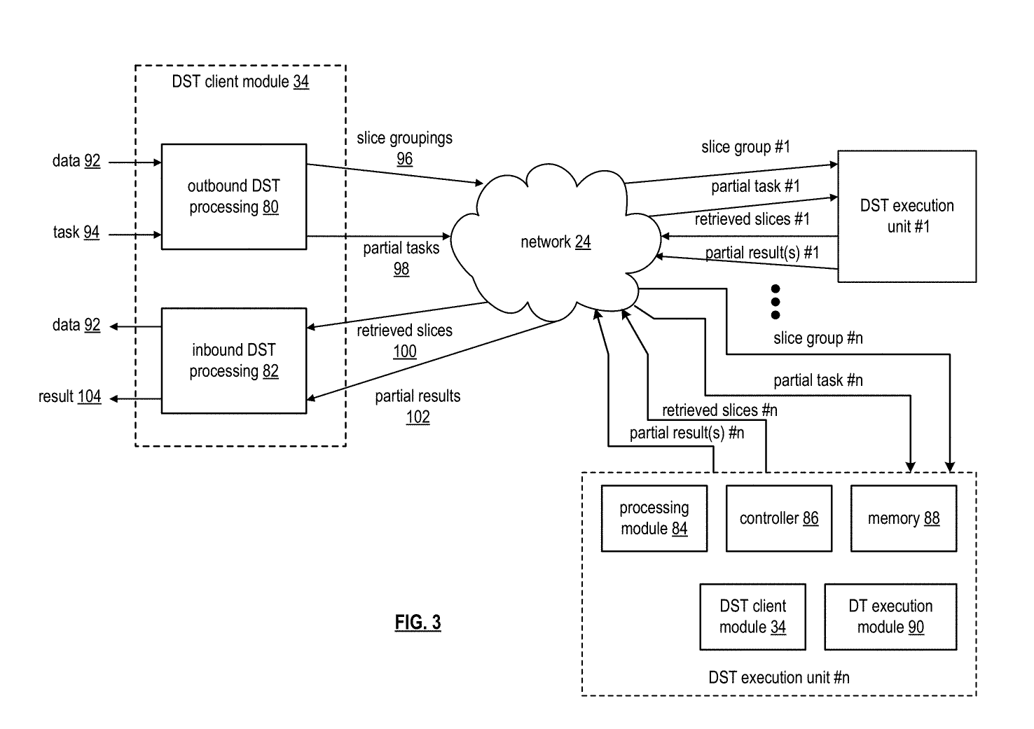

To support distributed task processing on received data, the distributed computing system 10 has two primary operations: DST (distributed storage and/or task processing) management and DST execution on received data (an example of which will be discussed with reference to FIGS. 3-19). With respect to the storage portion of the DST management, the DSTN managing unit 18 functions as previously described. With respect to the tasking processing of the DST management, the DSTN managing unit 18 performs distributed task processing (DTP) management services. One such DTP management service includes the DSTN managing unit 18 establishing DTP parameters (e.g., user-vault affiliation information, billing information, user-task information, etc.) for a user device 12-14 individually or as part of a group of user devices.

Another DTP management service includes the DSTN managing unit 18 performing DTP network operations, network administration (which is essentially the same as described above), and/or network maintenance (which is essentially the same as described above). Network operations include, but are not limited to, authenticating user task processing requests (e.g., valid request, valid user, etc.), authenticating results and/or partial results, establishing DTP authentication credentials for user devices, adding/deleting components (e.g., user devices, DST execution units, and/or DST processing units) from the distributed computing system, and/or establishing DTP authentication credentials for DST execution units.

To support distributed task processing on stored data, the distributed computing system 10 has two primary operations: DST (distributed storage and/or task) management and DST execution on stored data. With respect to the DST execution on stored data, if the second type of user device 14 has a task request 38 for execution by the DSTN module 22, it sends the task request 38 to the DST processing unit 16 via its interface 30. An example of DST execution on stored data will be discussed in greater detail with reference to FIGS. 27-39. With respect to the DST management, it is substantially similar to the DST management to support distributed task processing on received data.

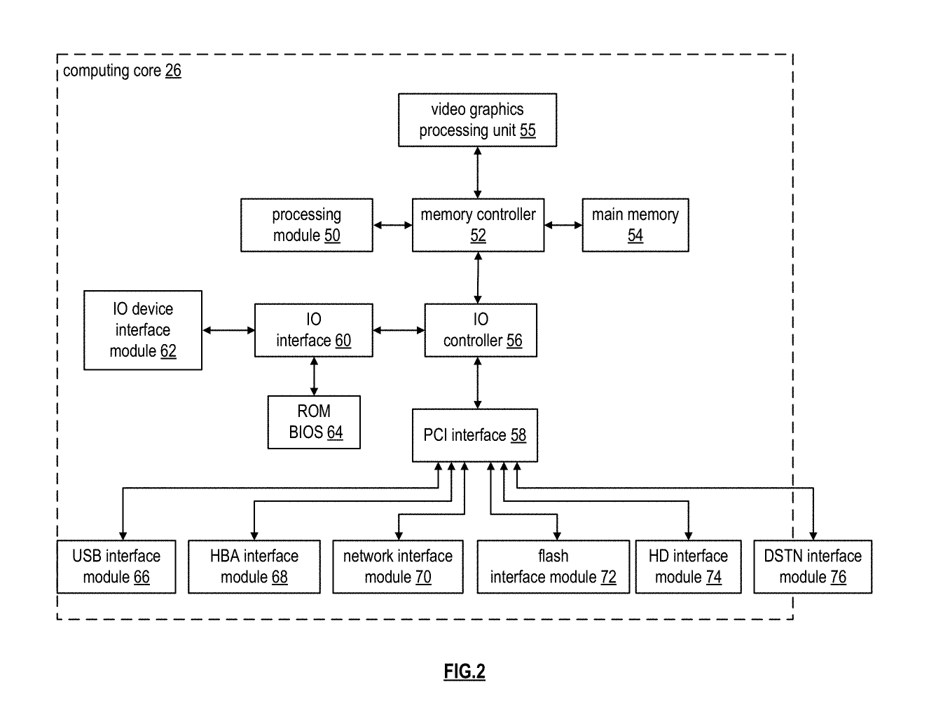

FIG. 2 is a schematic block diagram of an embodiment of a computing core 26 that includes a processing module 50, a memory controller 52, main memory 54, a video graphics processing unit 55, an input/output (IO) controller 56, a peripheral component interconnect (PCI) interface 58, an IO interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSTN interface module 76.

The DSTN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSTN interface module 76 and/or the network interface module 70 may function as the interface 30 of the user device 14 of FIG. 1. Further note that the IO device interface module 62 and/or the memory interface modules may be collectively or individually referred to as IO ports.

FIG. 3 is a diagram of an example of the distributed computing system performing a distributed storage and task processing operation. The distributed computing system includes a DST (distributed storage and/or task) client module 34 (which may be in user device 14 and/or in DST processing unit 16 of FIG. 1), a network 24, a plurality of DST execution units 1-n that includes two or more DST execution units 36 of FIG. 1 (which form at least a portion of DSTN module 22 of FIG. 1), a DST managing module (not shown), and a DST integrity verification module (not shown). The DST client module 34 includes an outbound DST processing section 80 and an inbound DST processing section 82. Each of the DST execution units 1-n includes a controller 86, a processing module 84, memory 88, a DT (distributed task) execution module 90, and a DST client module 34.

In an example of operation, the DST client module 34 receives data 92 and one or more tasks 94 to be performed upon the data 92. The data 92 may be of any size and of any content, where, due to the size (e.g., greater than a few Terabytes), the content (e.g., secure data, etc.), and/or task(s) (e.g., MIPS intensive), distributed processing of the task(s) on the data is desired. For example, the data 92 may be one or more digital books, a copy of a company's emails, a large-scale Internet search, a video security file, one or more entertainment video files (e.g., television programs, movies, etc.), data files, and/or any other large amount of data (e.g., greater than a few Terabytes).

Within the DST client module 34, the outbound DST processing section 80 receives the data 92 and the task(s) 94. The outbound DST processing section 80 processes the data 92 to produce slice groupings 96. As an example of such processing, the outbound DST processing section 80 partitions the data 92 into a plurality of data partitions. For each data partition, the outbound DST processing section 80 dispersed storage (DS) error encodes the data partition to produce encoded data slices and groups the encoded data slices into a slice grouping 96. In addition, the outbound DST processing section 80 partitions the task 94 into partial tasks 98, where the number of partial tasks 98 may correspond to the number of slice groupings 96.

The outbound DST processing section 80 then sends, via the network 24, the slice groupings 96 and the partial tasks 98 to the DST execution units 1-n of the DSTN module 22 of FIG. 1. For example, the outbound DST processing section 80 sends slice group 1 and partial task 1 to DST execution unit 1. As another example, the outbound DST processing section 80 sends slice group #n and partial task #n to DST execution unit #n.

Each DST execution unit performs its partial task 98 upon its slice group 96 to produce partial results 102. For example, DST execution unit #1 performs partial task #1 on slice group #1 to produce a partial result #1, for results. As a more specific example, slice group #1 corresponds to a data partition of a series of digital books and the partial task #1 corresponds to searching for specific phrases, recording where the phrase is found, and establishing a phrase count. In this more specific example, the partial result #1 includes information as to where the phrase was found and includes the phrase count.

Upon completion of generating their respective partial results 102, the DST execution units send, via the network 24, their partial results 102 to the inbound DST processing section 82 of the DST client module 34. The inbound DST processing section 82 processes the received partial results 102 to produce a result 104. Continuing with the specific example of the preceding paragraph, the inbound DST processing section 82 combines the phrase count from each of the DST execution units 36 to produce a total phrase count. In addition, the inbound DST processing section 82 combines the ‘where the phrase was found’ information from each of the DST execution units 36 within their respective data partitions to produce ‘where the phrase was found’ information for the series of digital books.

In another example of operation, the DST client module 34 requests retrieval of stored data within the memory of the DST execution units 36 (e.g., memory of the DSTN module). In this example, the task 94 is retrieve data stored in the memory of the DSTN module. Accordingly, the outbound DST processing section 80 converts the task 94 into a plurality of partial tasks 98 and sends the partial tasks 98 to the respective DST execution units 1-n.

In response to the partial task 98 of retrieving stored data, a DST execution unit 36 identifies the corresponding encoded data slices 100 and retrieves them. For example, DST execution unit #1 receives partial task #1 and retrieves, in response thereto, retrieved slices #1. The DST execution units 36 send their respective retrieved slices 100 to the inbound DST processing section 82 via the network 24.

The inbound DST processing section 82 converts the retrieved slices 100 into data 92. For example, the inbound DST processing section 82 de-groups the retrieved slices 100 to produce encoded slices per data partition. The inbound DST processing section 82 then DS error decodes the encoded slices per data partition to produce data partitions. The inbound DST processing section 82 de-partitions the data partitions to recapture the data 92.

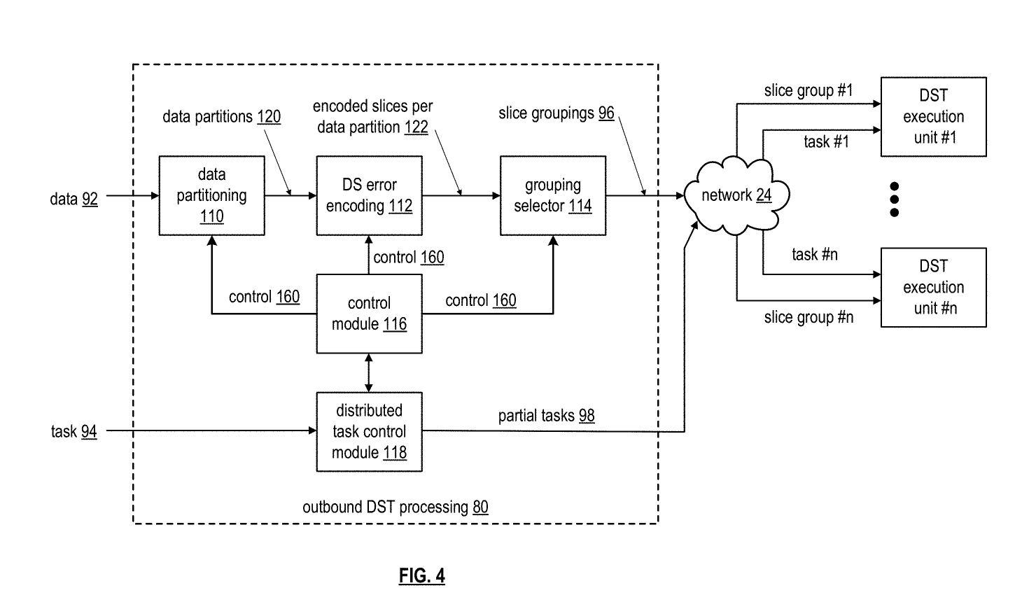

FIG. 4 is a schematic block diagram of an embodiment of an outbound distributed storage and/or task (DST) processing section 80 of a DST client module 34 FIG. 1 coupled to a DSTN module 22 of a FIG. 1 (e.g., a plurality of n DST execution units 36) via a network 24. The outbound DST processing section 80 includes a data partitioning module 110, a dispersed storage (DS) error encoding module 112, a grouping selector module 114, a control module 116, and a distributed task control module 118.

In an example of operation, the data partitioning module 110 partitions data 92 into a plurality of data partitions 120. The number of partitions and the size of the partitions may be selected by the control module 116 via control 160 based on the data 92 (e.g., its size, its content, etc.), a corresponding task 94 to be performed (e.g., simple, complex, single step, multiple steps, etc.), DS encoding parameters (e.g., pillar width, decode threshold, write threshold, segment security parameters, slice security parameters, etc.), capabilities of the DST execution units 36 (e.g., processing resources, availability of processing recourses, etc.), and/or as may be inputted by a user, system administrator, or other operator (human or automated). For example, the data partitioning module 110 partitions the data 92 (e.g., 100 Terabytes) into 100,000 data segments, each being 1 Gigabyte in size. Alternatively, the data partitioning module 110 partitions the data 92 into a plurality of data segments, where some of data segments are of a different size, are of the same size, or a combination thereof.

The DS error encoding module 112 receives the data partitions 120 in a serial manner, a parallel manner, and/or a combination thereof. For each data partition 120, the DS error encoding module 112 DS error encodes the data partition 120 in accordance with control information 160 from the control module 116 to produce encoded data slices 122. The DS error encoding includes segmenting the data partition into data segments, segment security processing (e.g., encryption, compression, watermarking, integrity check (e.g., CRC), etc.), error encoding, slicing, and/or per slice security processing (e.g., encryption, compression, watermarking, integrity check (e.g., CRC), etc.). The control information 160 indicates which steps of the DS error encoding are active for a given data partition and, for active steps, indicates the parameters for the step. For example, the control information 160 indicates that the error encoding is active and includes error encoding parameters (e.g., pillar width, decode threshold, write threshold, read threshold, type of error encoding, etc.).

The grouping selector module 114 groups the encoded slices 122 of a data partition into a set of slice groupings 96. The number of slice groupings corresponds to the number of DST execution units 36 identified for a particular task 94. For example, if five DST execution units 36 are identified for the particular task 94, the group selecting module groups the encoded slices 122 of a data partition into five slice groupings 96. The grouping selector module 114 outputs the slice groupings 96 to the corresponding DST execution units 36 via the network 24.

The distributed task control module 118 receives the task 94 and converts the task 94 into a set of partial tasks 98. For example, the distributed task control module 118 receives a task to find where in the data (e.g., a series of books) a phrase occurs and a total count of the phrase usage in the data. In this example, the distributed task control module 118 replicates the task 94 for each DST execution unit 36 to produce the partial tasks 98. In another example, the distributed task control module 118 receives a task to find where in the data a first phrase occurs, where in the data a second phrase occurs, and a total count for each phrase usage in the data. In this example, the distributed task control module 118 generates a first set of partial tasks 98 for finding and counting the first phase and a second set of partial tasks for finding and counting the second phrase. The distributed task control module 118 sends respective first and/or second partial tasks 98 to each DST execution unit 36.

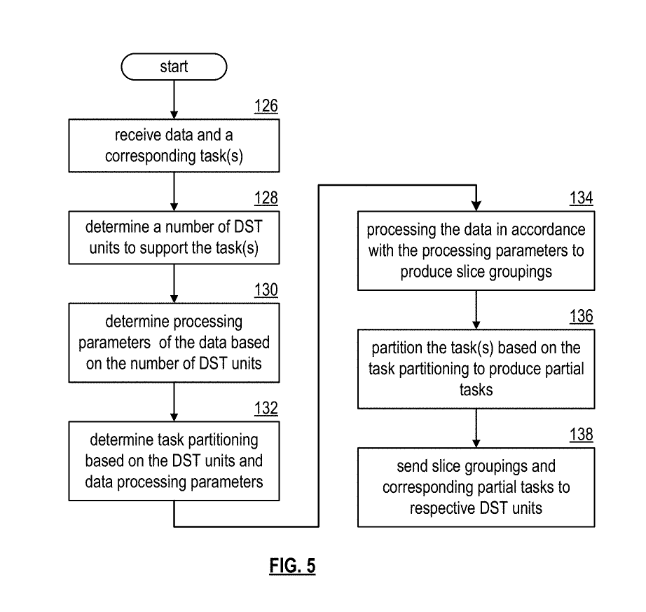

FIG. 5 is a logic diagram of an example of a method for outbound distributed storage and task (DST) processing that begins at step 126 where a DST client module receives data and one or more corresponding tasks. The method continues at step 128 where the DST client module determines a number of DST units to support the task for one or more data partitions. For example, the DST client module may determine the number of DST units to support the task based on the size of the data, the requested task, the content of the data, a predetermined number (e.g., user indicated, system administrator determined, etc.), available DST units, capability of the DST units, and/or any other factor regarding distributed task processing of the data. The DST client module may select the same DST units for each data partition, may select different DST units for the data partitions, or a combination thereof.

The method continues at step 130 where the DST client module determines processing parameters of the data based on the number of DST units selected for distributed task processing. The processing parameters include data partitioning information, DS encoding parameters, and/or slice grouping information. The data partitioning information includes a number of data partitions, size of each data partition, and/or organization of the data partitions (e.g., number of data blocks in a partition, the size of the data blocks, and arrangement of the data blocks). The DS encoding parameters include segmenting information, segment security information, error encoding information (e.g., dispersed storage error encoding function parameters including one or more of pillar width, decode threshold, write threshold, read threshold, generator matrix), slicing information, and/or per slice security information. The slice grouping information includes information regarding how to arrange the encoded data slices into groups for the selected DST units. As a specific example, if the DST client module determines that five DST units are needed to support the task, then it determines that the error encoding parameters include a pillar width of five and a decode threshold of three.

The method continues at step 132 where the DST client module determines task partitioning information (e.g., how to partition the tasks) based on the selected DST units and data processing parameters. The data processing parameters include the processing parameters and DST unit capability information. The DST unit capability information includes the number of DT (distributed task) execution units, execution capabilities of each DT execution unit (e.g., MIPS capabilities, processing resources (e.g., quantity and capability of microprocessors, CPUs, digital signal processors, co-processor, microcontrollers, arithmetic logic circuitry, and/or and the other analog and/or digital processing circuitry), availability of the processing resources, memory information (e.g., type, size, availability, etc.)), and/or any information germane to executing one or more tasks.

The method continues at step 134 where the DST client module processes the data in accordance with the processing parameters to produce slice groupings. The method continues at step 136 where the DST client module partitions the task based on the task partitioning information to produce a set of partial tasks. The method continues at step 138 where the DST client module sends the slice groupings and the corresponding partial tasks to respective DST units.

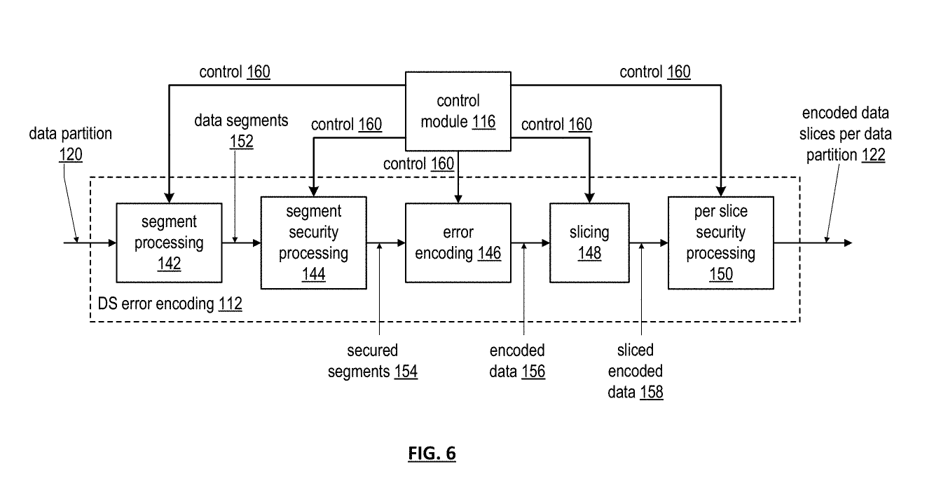

FIG. 6 is a schematic block diagram of an embodiment of the dispersed storage (DS) error encoding module 112 of an outbound distributed storage and task (DST) processing section. The DS error encoding module 112 includes a segment processing module 142, a segment security processing module 144, an error encoding module 146, a slicing module 148, and a per slice security processing module 150. Each of these modules is coupled to a control module 116 to receive control information 160 therefrom.

In an example of operation, the segment processing module 142 receives a data partition 120 from a data partitioning module and receives segmenting information as the control information 160 from the control module 116. The segmenting information indicates how the segment processing module 142 is to segment the data partition 120. For example, the segmenting information indicates how many rows to segment the data based on a decode threshold of an error encoding scheme, indicates how many columns to segment the data into based on a number and size of data blocks within the data partition 120, and indicates how many columns to include in a data segment 152. The segment processing module 142 segments the data 120 into data segments 152 in accordance with the segmenting information.

The segment security processing module 144, when enabled by the control module 116, secures the data segments 152 based on segment security information received as control information 160 from the control module 116. The segment security information includes data compression, encryption, watermarking, integrity check (e.g., cyclic redundancy check (CRC), etc.), and/or any other type of digital security. For example, when the segment security processing module 144 is enabled, it may compress a data segment 152, encrypt the compressed data segment, and generate a CRC value for the encrypted data segment to produce a secure data segment 154. When the segment security processing module 144 is not enabled, it passes the data segments 152 to the error encoding module 146 or is bypassed such that the data segments 152 are provided to the error encoding module 146.

The error encoding module 146 encodes the secure data segments 154 in accordance with error correction encoding parameters received as control information 160 from the control module 116. The error correction encoding parameters (e.g., also referred to as dispersed storage error coding parameters) include identifying an error correction encoding scheme (e.g., forward error correction algorithm, a Reed-Solomon based algorithm, an online coding algorithm, an information dispersal algorithm, etc.), a pillar width, a decode threshold, a read threshold, a write threshold, etc. For example, the error correction encoding parameters identify a specific error correction encoding scheme, specifies a pillar width of five, and specifies a decode threshold of three. From these parameters, the error encoding module 146 encodes a data segment 154 to produce an encoded data segment 156.

The slicing module 148 slices the encoded data segment 156 in accordance with the pillar width of the error correction encoding parameters received as control information 160. For example, if the pillar width is five, the slicing module 148 slices an encoded data segment 156 into a set of five encoded data slices. As such, for a plurality of encoded data segments 156 for a given data partition, the slicing module outputs a plurality of sets of encoded data slices 158.

The per slice security processing module 150, when enabled by the control module 116, secures each encoded data slice 158 based on slice security information received as control information 160 from the control module 116. The slice security information includes data compression, encryption, watermarking, integrity check (e.g., CRC, etc.), and/or any other type of digital security. For example, when the per slice security processing module 150 is enabled, it compresses an encoded data slice 158, encrypts the compressed encoded data slice, and generates a CRC value for the encrypted encoded data slice to produce a secure encoded data slice 122. When the per slice security processing module 150 is not enabled, it passes the encoded data slices 158 or is bypassed such that the encoded data slices 158 are the output of the DS error encoding module 112. Note that the control module 116 may be omitted and each module stores its own parameters.

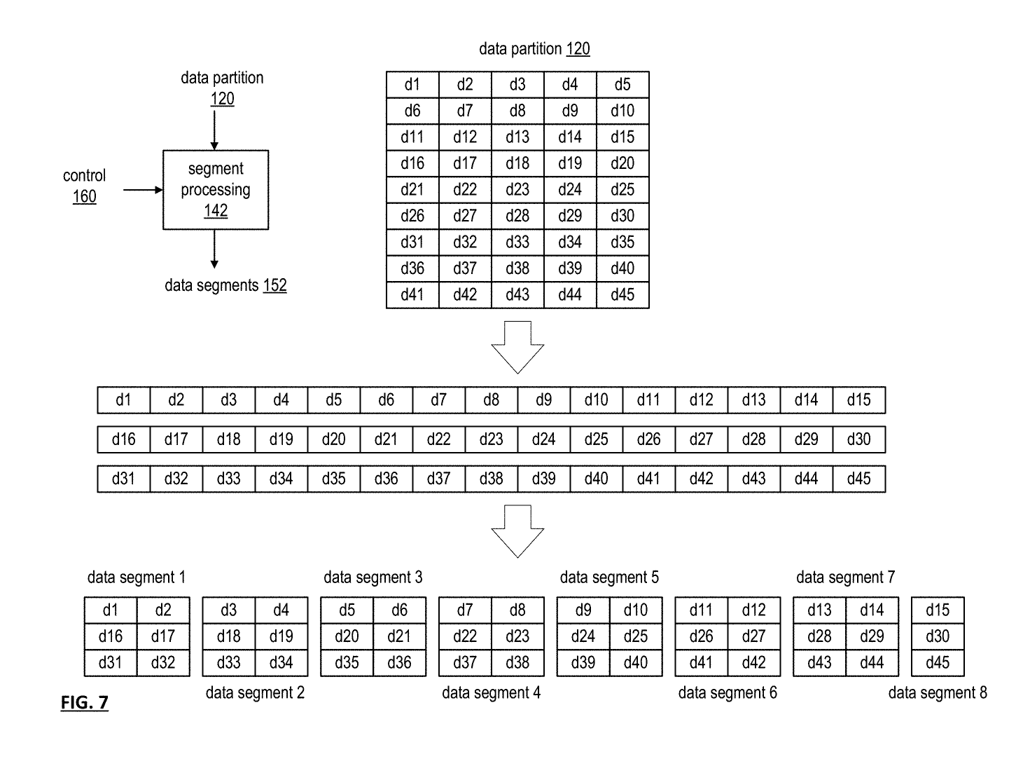

FIG. 7 is a diagram of an example of a segment processing of a dispersed storage (DS) error encoding module. In this example, a segment processing module 142 receives a data partition 120 that includes 45 data blocks (e.g., d1-d45), receives segmenting information (i.e., control information 160) from a control module, and segments the data partition 120 in accordance with the control information 160 to produce data segments 152. Each data block may be of the same size as other data blocks or of a different size. In addition, the size of each data block may be a few bytes to megabytes of data. As previously mentioned, the segmenting information indicates how many rows to segment the data partition into, indicates how many columns to segment the data partition into, and indicates how many columns to include in a data segment.

In this example, the decode threshold of the error encoding scheme is three; as such the number of rows to divide the data partition into is three. The number of columns for each row is set to 15, which is based on the number and size of data blocks. The data blocks of the data partition are arranged in rows and columns in a sequential order (i.e., the first row includes the first 15 data blocks; the second row includes the second 15 data blocks; and the third row includes the last 15 data blocks).

With the data blocks arranged into the desired sequential order, they are divided into data segments based on the segmenting information. In this example, the data partition is divided into 8 data segments; the first 7 include 2 columns of three rows and the last includes 1 column of three rows. Note that the first row of the 8 data segments is in sequential order of the first 15 data blocks; the second row of the 8 data segments in sequential order of the second 15 data blocks; and the third row of the 8 data segments in sequential order of the last 15 data blocks. Note that the number of data blocks, the grouping of the data blocks into segments, and size of the data blocks may vary to accommodate the desired distributed task processing function.

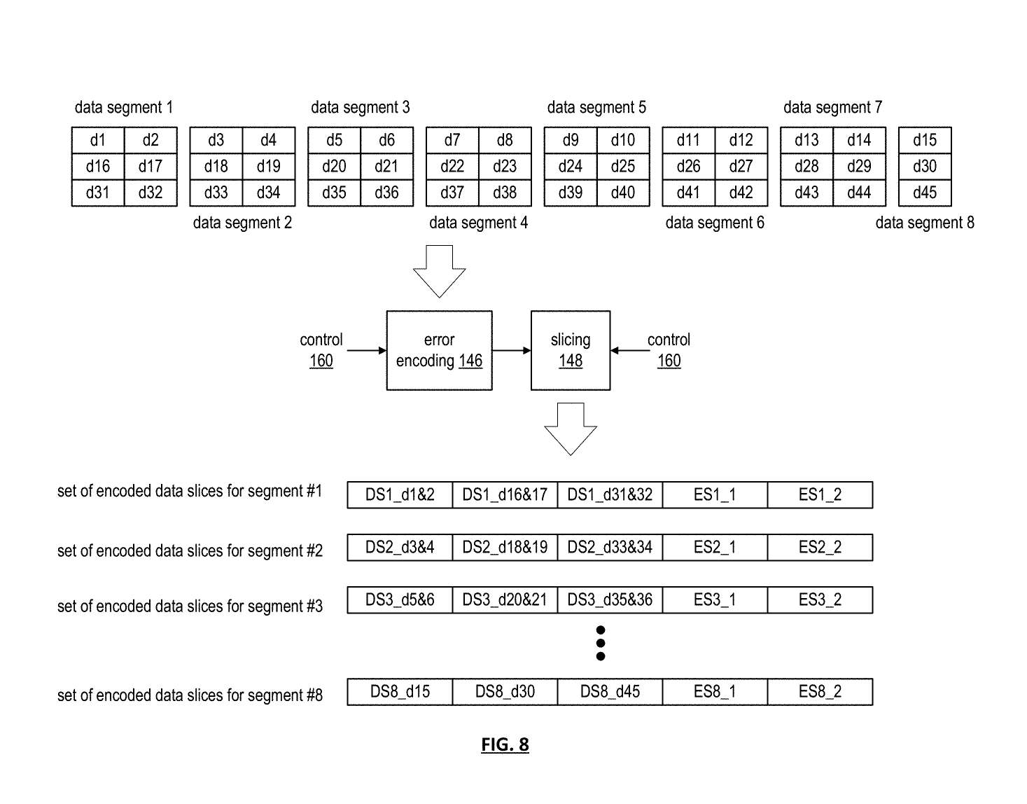

FIG. 8 is a diagram of an example of error encoding and slicing processing of the dispersed error encoding processing the data segments of FIG. 7. In this example, data segment 1 includes 3 rows with each row being treated as one word for encoding. As such, data segment 1 includes three words for encoding: word 1 including data blocks d1 and d2, word 2 including data blocks d16 and d17, and word 3 including data blocks d31 and d32. Each of data segments 2-7 includes three words where each word includes two data blocks. Data segment 8 includes three words where each word includes a single data block (e.g., d15, d30, and d45).

In operation, an error encoding module 146 and a slicing module 148 convert each data segment into a set of encoded data slices in accordance with error correction encoding parameters as control information 160. More specifically, when the error correction encoding parameters indicate a unity matrix Reed-Solomon based encoding algorithm, 5 pillars, and decode threshold of 3, the first three encoded data slices of the set of encoded data slices for a data segment are substantially similar to the corresponding word of the data segment. For instance, when the unity matrix Reed-Solomon based encoding algorithm is applied to data segment 1, the content of the first encoded data slice (DS1_d1&2) of the first set of encoded data slices (e.g., corresponding to data segment 1) is substantially similar to content of the first word (e.g., d1 & d2); the content of the second encoded data slice (DS1_d16&17) of the first set of encoded data slices is substantially similar to content of the second word (e.g., d16 & d17); and the content of the third encoded data slice (DS1_d31&32) of the first set of encoded data slices is substantially similar to content of the third word (e.g., d31 & d32).

The content of the fourth and fifth encoded data slices (e.g., ES1_1 and ES1_2) of the first set of encoded data slices include error correction data based on the first-third words of the first data segment. With such an encoding and slicing scheme, retrieving any three of the five encoded data slices allows the data segment to be accurately reconstructed.

The encoding and slices of data segments 2-7 yield sets of encoded data slices similar to the set of encoded data slices of data segment 1. For instance, the content of the first encoded data slice (DS2_d3&4) of the second set of encoded data slices (e.g., corresponding to data segment 2) is substantially similar to content of the first word (e.g., d3 & d4); the content of the second encoded data slice (DS2_d18&19) of the second set of encoded data slices is substantially similar to content of the second word (e.g., d18 & d19); and the content of the third encoded data slice (DS2_d33&34) of the second set of encoded data slices is substantially similar to content of the third word (e.g., d33 & d34). The content of the fourth and fifth encoded data slices (e.g., ES1_1 and ES1_2) of the second set of encoded data slices includes error correction data based on the first-third words of the second data segment.

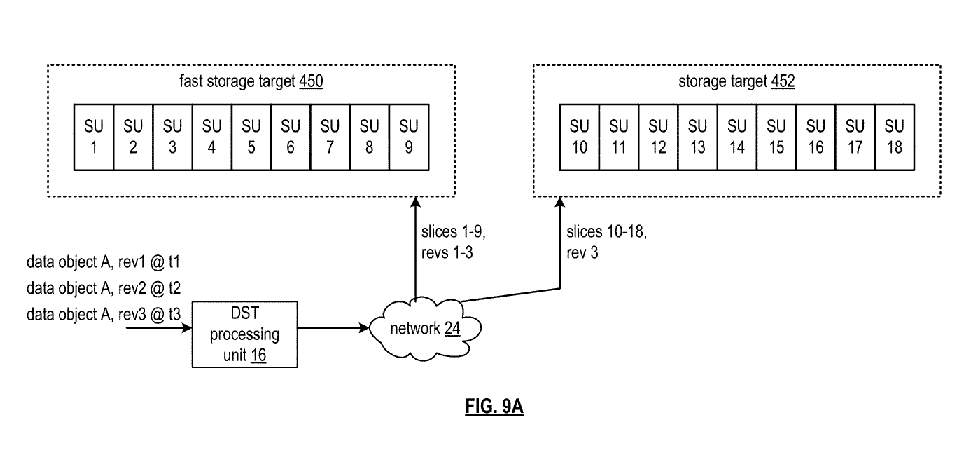

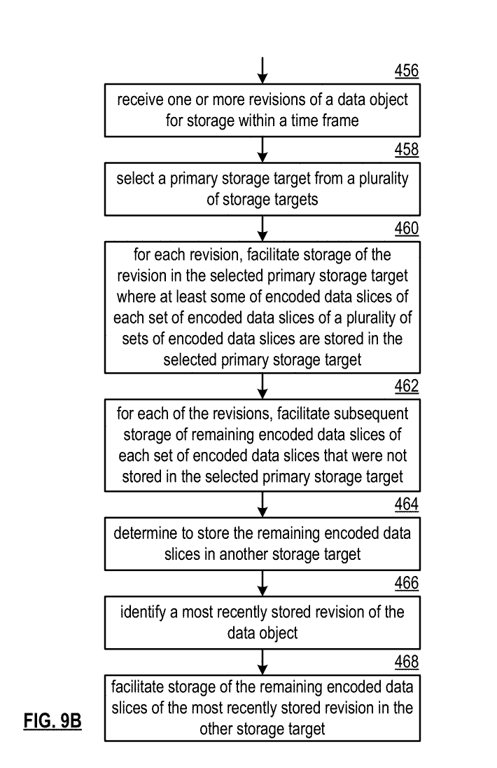

FIG. 9A is a schematic block diagram of another embodiment of a dispersed storage network (DSN) that includes a fast storage target 450, a storage target 452, the network 24 of FIG. 1, and the distributed storage and task (DST) processing unit 16 of FIG. 1. The fast storage target 450 includes a first group of storage units and the storage target 452 includes a second group of storage units. Each storage unit may be implemented utilizing the DST execution unit 36 of FIG. 1. Together, the storage units of the fast storage target 450 and the storage target 452 combine to form an information dispersal algorithm (IDA) width number of storage units as a set of storage units for storage of sets of encoded data slices, where the IDA width is greater than or equal to twice a decode threshold associated with the IDA (e.g., a so-called eventual consistency configuration). Each of the fast storage target 450 and the storage target 452 include at least a decode threshold number of storage units. The fast storage target 450 and storage target 452 may be implemented at different sites of the DSN.

The DSN is operable to store data in the storage units as sets of encoded data slices. In an example of operation of the storing of the data, the DST processing unit 16 receives one or more revisions of the data object for storage within a time frame. For example, the DST processing unit 16 receives a first revision of a data object A at time 1, receives a second revision of the data object A at time 2, and receives a third revision of the data object A at time 3. The receiving may further include receiving a data identifier of the data object and a revision identifier associated with the revision of the data object.

Having received a revision of the data object, the DST processing unit 16 selects a primary storage target from a plurality of storage targets. The selecting may be based on one or more of performance levels of storage units of the storage targets. For example, the DST processing unit 16 selects the fast storage target 450 when storage units of the fast storage target are associated with improved performance levels (e.g., higher sustained bandwidth of access, lower access latency times, etc.) as compared to storage units of the storage target.

For each of the revisions, the DST processing unit 16 facilitates storage of the revision of the data object in the selected primary storage target. For example, the DST processing unit 16 dispersed storage error encodes the revision of the data object to produce a plurality of sets of encoded data slices, and sends, for each set of encoded data slices, at least some of the encoded data slices to storage units of the selected primary storage target. For instance, the DST processing unit 16 produces the plurality of sets of encoded data slices to include 18 encoded data slices in each set and sends, via the network 24, encoded data slices 1-9 of each of the plurality of sets of encoded data slices of the revision to the storage units 1-9 of the fast storage target for storage.

For each of the revisions, the DST processing unit 16 facilitates subsequent storage of remaining encoded data slices of each set of encoded data slices. The facilitating includes temporarily storing the remaining encoded data slices in a memory of the DST processing unit 16. Having facilitated the subsequent storage, the DST processing unit 16 determines whether to store encoded data slices in another storage target. The DST processing unit 16 indicates to store the encoded data slices in the other storage target based on one or more of when a timeframe expires without receiving another revision of the data object, in accordance with a schedule, based on a number of temporarily stored revisions matching a maximum number of revisions for temporary storage, and receiving a request. For example, the DST processing unit 16 determines to store encoded data slices of revision 3 in the storage target when the maximum number of revisions for temporary storage is three.

When storing encoded data slices in the other storage target, the DST processing unit 16 identifies a most recently stored revision of the data object. The identifying includes at least one of performing a lookup, initiating a query, and interpreting a query response. For example, the DST processing unit 16 accesses the memory of the DST processing unit 16 and determines that revision 3 of the data object A is the most recently stored revision.

Having identified the most recently stored revision of the data object, the DST processing unit 16 facilitates storage of the remaining encoded data slices of each set of encoded data slices associated with the most recently stored revision and the data object in storage units of the other storage target. For example, the DST processing unit 16 issues, via the network 24, write slice requests to storage units 10-18 of the storage target, where the write slice requests includes the remaining encoded data slices of each of the set of encoded data slices associated with revision 3 of the data object.

FIG. 9B is a flowchart illustrating an example of storing data. The method begins or continues at step 456 where a processing module (e.g., of a distributed storage and task (DST) client unit) receives one or more revisions of a data object for storage within a time frame. The receiving may further include receiving a revision identifier for each revision. The method continues at step 458 where the processing module selects a primary storage target from a plurality of storage targets. The selecting may be based on identifying a storage target associated with a favorable performance level (e.g., best performance, performance greater than a minimum performance threshold level) as the primary storage target.

For each revision, the method continues at step 460 where the processing module facilitates storage of the revision in the selected primary storage target where at least some of the encoded data slices of each set of encoded data slices of a plurality of sets of encoded data slices are stored in the selected primary storage target. For example, the processing module dispersed storage error encodes the revision of the data object to produce a plurality of sets of encoded data slices and for each set, identifies encoded data slices associated with the primary storage target (e.g., slices corresponding to storage units of the primary storage target, where a number of storage units of the primary storage target is greater than or equal to a decode threshold number associated with the dispersed storage error coding), and sends the identified encoded data slices to the storage units of the primary storage target for storage.

For each of the revisions, the method continues at step 462 where the processing module facilitates subsequent storage of remaining encoded data slices of each set of encoded data slices that were not stored in the selected primary storage target. For example, the processing module temporarily stores (e.g., in a local memory) the remaining encoded data slices of each set of encoded data slices, stores the revision indicator, and stores the timestamp.

The method continues at step 464 where the processing module determines to store the remaining encoded data slices in another storage target. For example, the processing module indicates to store the remaining encoded data slices when a timeframe expires without receiving another revision of the data object. As another example, the processing module indicates to store the remaining encoded data slices in accordance with a schedule. As yet another example, the processing module indicates to store the remaining encoded data slices when a number of temporarily stored revisions is substantially the same as a maximum number of stored revisions. The determining to store the remaining encoded data slices and the other storage target further includes identifying the other storage target based on at least one of a lookup and performing a query. For example, the processing module identifies the other storage target as a storage target associated with the selected primary storage target.

The method continues at step 466 where the processing module identifies a most recently stored revision of the data object. The identifying includes at least one of interpreting a lookup, issuing a list slice request to a storage unit of the selected primary storage target, and interpreting a list slice response. The method continues at step 468 where the processing module facilitates storage of the remaining encoded data slices of the most recently stored revision in the other storage target. For example, the processing module sends the remaining encoded data slices of each set of encoded data slices of the plurality of sets of encoded data slices associated with the most recently stored revision to storage units of the other storage target.

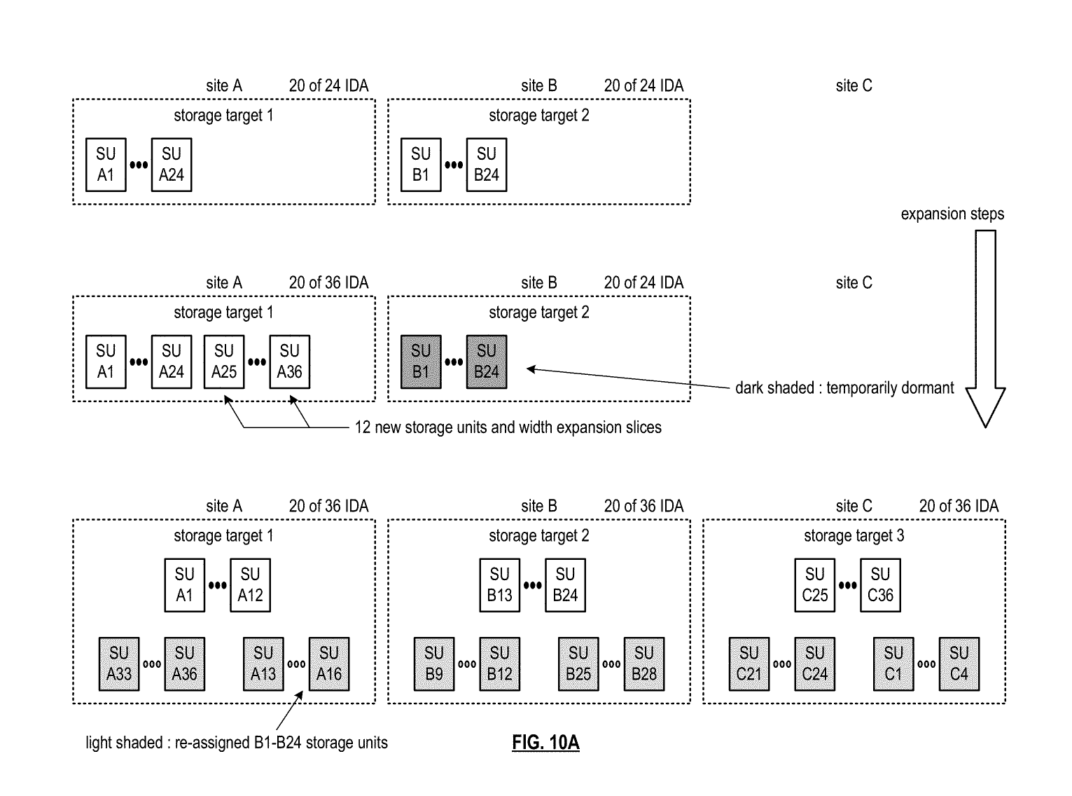

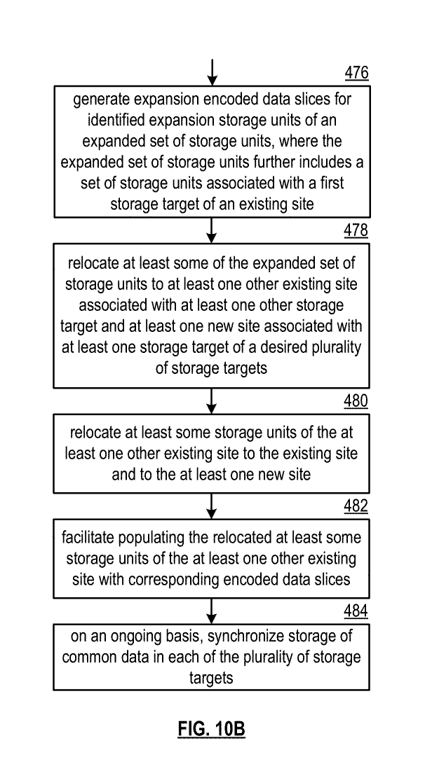

FIG. 10A is a schematic block diagram of another embodiment of a dispersed storage network (DSN) that includes two or more storage targets portrayed in a series of expansion steps, where another storage target is created for association with the two or more storage targets of a starting step. Each storage target includes a plurality of storage units. Each storage unit may be implemented utilizing the dispersed storage and task (DST) execution (EX) unit 36 of FIG. 1.

The DSN is operable to migrate stored data to facilitate expansion of the two or more storage targets. In an example of operation of the migrating of the stored data, the starting step portrays a storage target 1 implemented at a site A and a storage target 2 implemented at a site B. the storage target 1 initially includes storage units A1-A24 and the storage target 2 initially includes storage units B1-B24. Sets of encoded data slices may be generated in accordance with an information dispersal algorithm (IDA), where an IDA width number of encoded data slices included in each set of encoded data slices and a decode threshold number of encoded data slices are required to recover a data segment that was dispersed storage error encoded to produce the set of encoded data slices. For example, a decode threshold of 20 may be associated with each storage target when the IDA width of 24 is utilized. As such, 24 slices are stored in at least 24 storage units of the storage targets 1 and 2 and at least 20 slices are recovered from storage units of the storage targets 1 and 2 to recover a data segment.

In the example of operation of the migrating of the stored data to facilitate the expansion of the two storage targets to three storage targets, in a first step of the expansion steps, the storage units B1-B24 are inactivated to be temporarily dormant within the storage target 2. Having inactivated the storage units of the storage target 2, an expanded IDA width is selected. The selecting may be based on one or more of a predetermination, a desired number of storage units per storage target after the expansion of the storage targets, and a number of storage units present prior to the first step of the expansion steps. For example, an IDA width of 36 is selected to expand the 48 storage units to 60 storage units, where 20 storage units are implemented at each of three sites A, B, and C and at least a decode threshold number (e.g., decode threshold unchanged) of storage units are implemented at each of the sites (e.g., 20). For instance, 60-48=12 new storage units are required to provide storage for 12 additional encoded data slices per set of encoded data slices.

Having selected the expanded IDA width, the 12 new storage units are added to the storage target 1 such that storage target 1 temporarily includes the expanded IDA width number of storage units (e.g., 36). Having implemented the new storage units, expansion encoded data slices 25-36 are generated for each set of stored encoded data slices 1-24 and stored in the 12 new storage units. For instance, a DST client module 34 of FIG. 1 recovers, for each data segment, at least a decode threshold number of encoded data slices from storage units A1-A24, dispersed storage error decodes the recovered encoded data slices to reproduce a data segment, dispersed storage error encodes the reproduced data segment using an expanded encoding matrix to produce the expansion encoded data slices 25-36 for storage in the new storage units A25-A36.

In a second step of the expansion, the storage units at storage target 1 (e.g., storage units A1-A36) are equally divided amongst the three storage targets at the three sites for redeployment. For example, storage units A13-A24 are physically moved to site B and become part of storage target 2 as storage units B13-B24 and new storage units A25-A36 are physically moved to site C and become part of storage target 3 as storage units C25-C36. Encoded data slices 25-36 are still stored within the storage units C25-C36.

Having redeployed the storage units from the storage target 1, the storage units from the storage target 2 are evenly redeployed amongst the three storage targets. For example, eight storage units are deployed at each of the three sites. For instance, storage units B1-B8 are redeployed to storage target 1 and renamed as storage units A33-A36 and storage units A13-A16 such that storage target 1 now includes 20 storage units A33-A16. Having redeployed the storage units, encoded data slices are copied from corresponding storage units of the other storage targets to populate the redeployed storage units with a corresponding encoded data slices. For example, encoded data slices 33-36 are copied from storage units C33-C36 at storage target 3 to populate storage units A33-A36. In a similar fashion, 8 storage units from the original storage units B1-B24 are redeployed and populated with encoded data slices at storage target 2 and at storage target 3.

While moving the storage units of the non-expanded site, the DSN may utilize the expanded set of storage units as a temporary common storage target (e.g., storage units A1-A36). Once all storage units have been redeployed and repopulated with encoded data slices, the three storage targets may perform eventual consistency synchronization operations to maintain at least a decode threshold number of encoded data slices of the storage targets as a first priority and to maintain further encoded data slices of most recent revisions as a second priority.

FIG. 10B is a flowchart illustrating an example of migrating stored data. The method begins or continues at step 476 where a processing module (e.g., of a distributed storage and task (DST) client module) generates expansion encoded data slices for identified expansion storage units of an expanded set of storage units, where the expanded set of storage units further includes a set of storage units associated with a first storage target of an existing site. For example, for each set of existing stored encoded data slices, the processing module recovers a decode threshold number of slices, dispersed storage error decodes the recovered slices to reproduce a data segment, dispersed storage error encodes the data segment with an expanded encoding matrix to produce the expansion encoded data slices, and facilitate storage of the expansion encoded data slices in the identified expansion storage units.

The method continues at step 478 where the processing module relocates at least some of the expanded set of storage units to at least one other existing site associated with at least one other storage target and at least one new site associated with at least one storage target of a desired plurality of storage targets. For example, the processing module selects at least some of the expanded set of storage units (e.g., equally divides amongst the desired plurality of storage targets) and indicates the selection for re-location keeping stored encoded data slices intact.

The method continues at step 480 where the processing module relocates at least some storage units of the at least one other existing site to the existing site and to the at least one new site. For example, the processing module selects at least some of the storage units and indicates the selection for relocation.

The method continues at step 482 where the processing module facilitates population of the relocated at least some storage units of the at least one other existing site with corresponding encoded data slices. For example, the processing module rebuilds encoded data slices based on decoding at least a decode threshold number of encoded data slices per set of encoded data slices. As another example, the processing module copies encoded data slices from corresponding storage units of the expanded set of storage units.

The method continues at step 484 where, on an ongoing basis, the processing module synchronizes storage of common data in each of the plurality of storage targets. For example, the processing module maintains same revisions of encoded data slices stored in storage units of the plurality of storage targets.

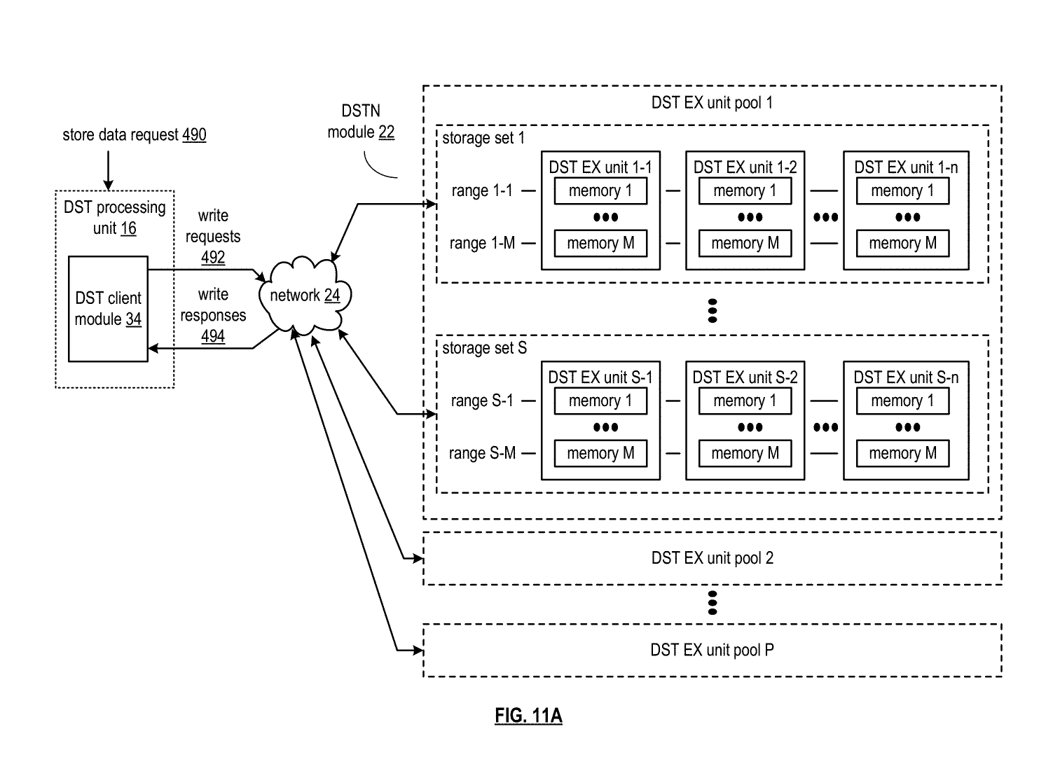

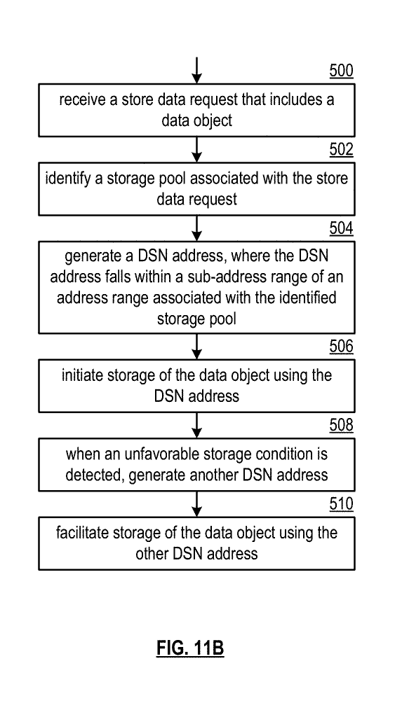

FIG. 11A is a schematic block diagram of another embodiment of a dispersed storage network (DSN) that includes the distributed storage and task (DST) processing unit 16 of FIG. 1, the network 24 of FIG. 1, and the distributed storage and task network (DSTN) module 22 of FIG. 1. The DST processing unit 16 includes the DST client module 34 of FIG. 1. The DSTN module 22 includes a plurality of DST execution (EX) unit pools 1-P. each DST execution unit pool includes one or more storage sets 1-S. Each storage set includes a set of DST execution units 1-n. Each DST execution unit includes a plurality of memories 1-M. Each DST execution unit may be implemented utilizing the DST execution unit 36 of FIG. 1. Each memory of each storage set is associated with a DSN address range 1-M (e.g., range of slice names).

The DSN functions to store data in the DSTN module 22. In an example of operation of the storing of the data, the DST processing unit 16 receives a store data request 490. The store data request 490 includes one or more of a data object, a data object name, and a requester identity. Having received the store data request 490, the DST client module 34 identifies a storage pool associated with the store data request. The identifying includes at least one of performing a vault lookup based on the requester identity, performing a random selection, selecting based on available storage set storage capacity, and selecting based on storage set performance levels.

Having identified the storage pool, the DST client module 34 generates a DSN address, where the DSN address falls within an address range associated with a plurality of storage sets, where each storage set is associated with a plurality of address ranges, and where each address range is associated with a set of memories. For example, the DST client module 34 generates the DSN address based on a random number to produce an available DSN address within a plurality of address ranges of the identified storage pool read as another example, the DST client module 34 generates the DSN address based on memory said attributes such as performance and available capacity.

Having generated the DSN address, the DST client module 34 initiates storage of the data at the DSN address. For example, the DST client module 34 dispersed storage error encodes the data to produce a plurality of sets of encoded data slices and issues, via the network 24, one or more sets of write slice requests as write requests 492 that includes the plurality of sets of encoded data slices to be DST execution units associated with the DSN address. Having issued the write requests 492, the DST client module 34 receives write responses 494 from at least some of the DST execution units.

When an unfavorable condition is detected with regards to storage of the data at the DSN address (e.g., less than a write threshold number of favorable write responses have been received), the DST client module 34 generates another DSN address, where the other DSN address is associated with another set of memories (e.g., of the same set of DST execution units or from another set).

Having generated the other DSN address, the DST client module 34 facilitates storage of the data at the other DSN address. For example, the DST client module 34 resends the one or more sets of write slice requests 492 to a set of DST execution units associated with other set of memories. Having resent the one or more sets of write slice requests 492, the DST client module 34 may also update a DSN directory or equivalent to associate the data object name and the other DSN address.

FIG. 11B is a flowchart illustrating another example of storing data. The method begins or continues at step 500 where a processing module (e.g., of a distributed storage and task (DST) client module) receives a store data request that includes a data object. The receiving may include receiving a requester identity and a data object name. The method continues at step 502 where the processing module identifies a storage pool associated with the store data request. The identifying may include one or more of interpreting system registry information, interpreting a vault entry associated with the requester identifier, performing a random selection, selecting based on performance, and selecting based on available storage capacity.

The method continues at step 504 where the processing module generates a dispersed storage network (DSN) address, where the DSN address falls within a sub-address range of an address range associated with the identified storage pool. The generating may include at least one of generating a random address within the address range of the identified storage pool (e.g., to include a vault identifier and a random object number), selecting a next available DSN address, and selecting a DSN address associated with a set of memories associated with favorable performance and storage capacity.

The method continues at step 506 where the processing module initiates storage of the data object using the DSN address. For example, the processing module dispersed storage error encodes the data object to produce a plurality of sets of encoded data slices, generates a plurality of sets of slice names that includes the DSN address (e.g., include a slice index, and a segment number along with the vault identifier and the random object number), generates one or more sets of write slice requests that includes the plurality of sets of encoded data slices and the plurality of sets of slice names, and sends the one or more sets of write slice requests to a storage set associated with the DSN address.

When an unfavorable storage condition is detected, the method continues at step 508 where the processing module generates another DSN address. For example, the processing module detects the unfavorable storage condition (e.g., a time frame expires without receiving a write threshold number of favorable write slice responses), identifies a set of memories associated with the DSN address, selects another set of memories associated with favorable performance and available capacity, and generates a DSN address associated with the other set of memories as the other DSN address.

The method continues at step 510 where the processing module facilitates storage of the data object using the other DSN address. For example, the processing module issues write slice requests to storage units associated with the other set of memories, where the write slice requests includes the plurality of sets of encoded data slices. When receiving favorable write slice responses, the processing module associates the data object name and the other DSN address. For example, the processing module updates a DSN directory. As another example, the processing module updates a dispersed hierarchical index.

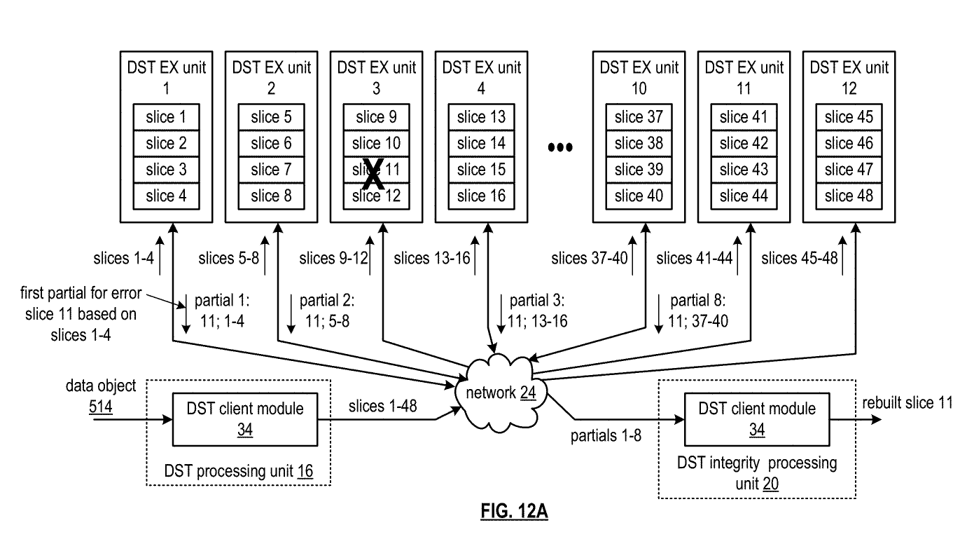

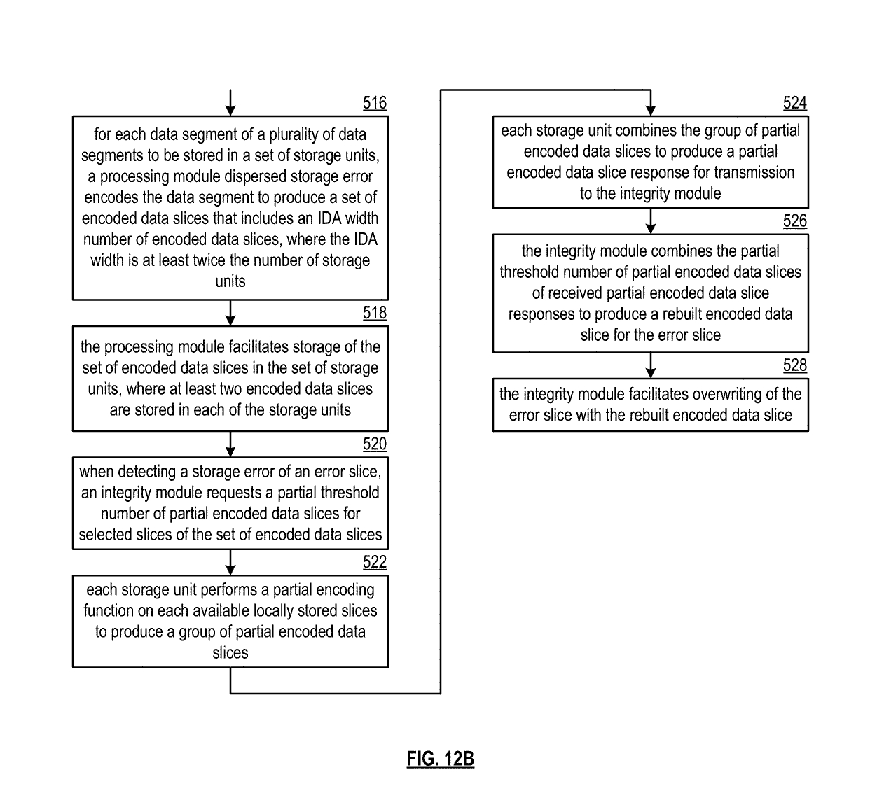

FIG. 12A is a schematic block diagram of another embodiment of a dispersed storage network (DSN) that includes a set of distributed storage and task (DST) execution (EX) units 1-12, the network 24 of FIG. 1, the DST processing unit 16 of FIG. 1, and the DST integrity processing unit 20 of FIG. 1. Each DST execution unit may be implemented utilizing the DST execution unit 36 of FIG. 1. The DST processing unit 16 includes the DST client module 34 of FIG. 1. The DST integrity processing unit 20 includes the DST client module 34 of FIG. 1. Alternatively, the DST client module 34 may be implemented in one or more of the DST execution units 1-12.

The DSN is operable to rebuild stored data when a storage error associated with an error slice has been detected. In an example of operation of the rebuilding of the stored data, the DST processing unit 16 divides a data object 514 into a plurality of data segments, dispersed storage error encodes each data segment to produce a set of encoded data slices that includes an information dispersal algorithm (IDA) width number of encoded data slices, where the IDA width is at least twice a number of DST execution units of the set of DST execution units. As such, two or more encoded data slices of each set of encoded data slices are stored in each DST execution unit of the set of DST execution units. For example, for encoded data slices are stored, via the network 24, in each of the set of DST execution units 1-12 when the IDA width is 48. Having generated the encoded data slices, the DST processing unit facilitates storage of each set of encoded data slices in the set of DST execution units, where at least two encoded data slices are stored in each DST execution unit (e.g., stored in one or more memories within each DST execution unit).

When detecting the storage error of the error slice, the integrity processing unit 20 requests, via the network 24, a partial threshold number of partial encoded data slices for selected slices of the set of encoded data slices that includes the error slice (e.g., encoded data slice to be rebuilt). For example, the DST integrity processing unit 20 requests 8 partial encoded data slices from eight DST execution units, where the eight partial encoded data slices are based on 32 stored encoded data slices of the set of 48 encoded data slices when the decode threshold number is 32 when detecting that the encoded data slice 11 is the error slice. As such, each of the partial encoded data slices is based on four stored encoded data slices within a particular DST execution unit.

Each DST execution unit receiving a partial encoded data slice request performs a partial encoding function on each available encoded data slice of the selected slices of the set of encoded data slices within the DST execution unit to produce one of the partial encoded data slices of the requested partial threshold number of partial encoded data slices. For example, the DST execution unit 1 obtains an encoding matrix utilized to generate the encoded data slice 11 to be rebuilt, reduces the encoding matrix to produce a square matrix that exclusively includes rows associated with the decode threshold number of selected slices, inverts the square matrix to produce an inverted matrix, matrix multiplies the inverted matrix by an encoded data slice associated with the DST EX unit to produce a vector, and matrix multiplies the vector by a row of the encoding matrix corresponding to the encoded data slice 11 to be rebuilt to produce the partial encoded data slice for the selected slice.

Having produced the partial encoded data slices for the selected slices, each DST execution unit that receives the partial encoded data slice request combines the partial encoded data slices of the DST execution unit to produce a single partial encoded data slice response for transmission, via the network 24, to the DST integrity processing unit 20. For example, the DST execution unit 1 adds the partial encoded data slices in the field under which the IDA arithmetic is implemented (e.g., exclusive OR) to produce partial encoded data slice 1 for error slice 11 based on encoded data slices 1-4. Having produced the single partial encoded data slice response, the DST execution units send, via the network 24, the single partial encoded data slice response to the DST integrity processing unit 20.

The DST integrity processing unit 20 receives the partial threshold number of partial encoded data slices 1-8 and combines the received partial encoded data slices to produce a rebuilt encoded data slice for the error slice. For example, the DST integrity processing unit 20 adds the received partial encoded data slices 1-8 in the field under which the IDA arithmetic is implemented. Having produced the rebuilt encoded data slice 11, the DST integrity processing unit 20 facilitates overwriting of the error slice with the rebuilt encoded data slice. For example, the DST integrity processing unit 20 issues, via the network 24, a write slice request to DST execution unit 3, where the write slice request includes the rebuilt encoded data slice for error slice 11.

FIG. 12B is a flowchart illustrating an example of rebuilding stored data. The method begins or continues at step 516 where a processing module (e.g., of a distributed storage and task (DST) client module), for each data segment of a plurality of data segments to be stored in a set of storage units, dispersed storage error encodes the data segment to produce a set of encoded data slices that includes an information dispersal algorithm (IDA) width number of encoded data slices, where the IDA width is at least twice the number of storage units.

The method continues at step 518 where the processing module facilitates storage of the set of encoded data slices in the set of storage units, where at least two encoded data slices are stored in each of the storage units. For example, the processing module issues a write slice requests to the storage units, where the storage unit stores the encoded data slices in one or more memories.

When detecting a storage error of an error slice, the method continues at step 520 where and integrity module requests a partial threshold number of partial and encoded data slices for selected slices of the set of encoded data slices. The detecting includes one or more of interpreting an error message, scanning slices, and detecting the error when a slice is missing or corrupted. The requesting includes issuing partial slice requests indicating the identity of the error slice and selected slices of the rebuilding process. The partial slice request may further include a rebuilding matrix.

The method continues at step 522 where each storage unit performs a partial encoding function on each available locally stored slices to produce a group of partial encoded data slices. For example, the storage unit performs a partial encoding function based on the slice to be rebuilt, the rebuilding matrix, and one or more locally stored slices. The rebuilding matrix is based on the selected slices for the rebuilding process (e.g., includes rows of an encoding matrix associated with the selected slices for the rebuilding process, where the selected slices includes a decode threshold number of slices).

The method continues at step 524 where each storage unit combines the group of partial encoded data slices to produce a partial encoded data slice response for transmission to the integrity module. For example, the storage unit adds the partial encoded data slices in a field under which the IDA arithmetic was implemented.

The method continues at step 526 where the integrity module combines the partial threshold number of partial encoded data slices of received partial encoded data slice responses to produce a rebuilt encoded data slice for the error slice. For example, the integrity module adds the received partial encoded data slices in the field under which the IDA arithmetic was implemented.

The method continues at step 528 where the integrity module facilitates overwriting of the error slice with the rebuilt encoded data slice. For example, the integrity module issues a write slice request to a storage unit associated with the error slice, where the write slice request includes the rebuilt encoded data slice.

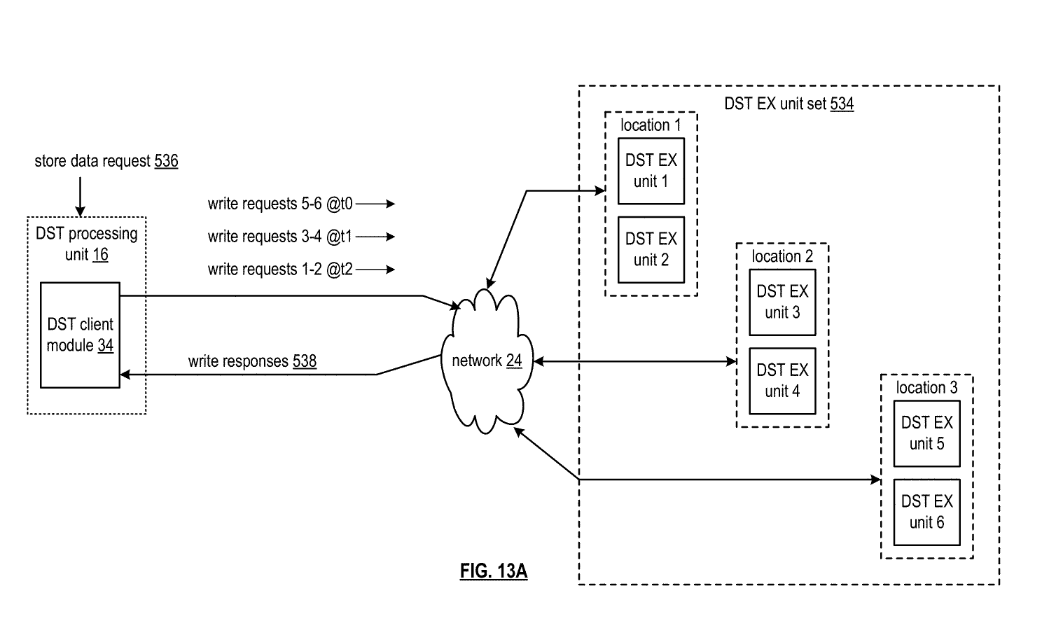

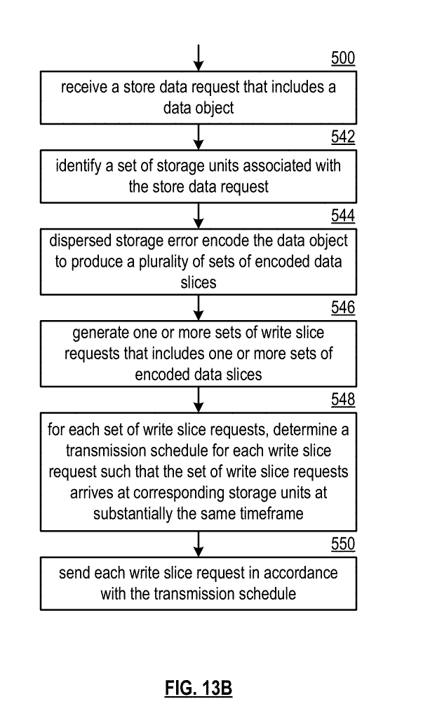

FIG. 13A is a schematic block diagram of another embodiment of a dispersed storage network (DSN) that includes the distributed storage and task (DST) processing unit 16 of FIG. 1, the network 24 of FIG. 1, and a DST execution (EX) unit set 534. The DST processing unit 16 includes the DST client module 34 of FIG. 1. The DST execution unit set 534 includes a plurality of locations 1-3, where each location includes at least one DST execution unit. Each DST execution unit may be implemented utilizing the DST execution unit 36 of FIG. 1. For example, the location 1 includes DST execution units 1-2, the location 2 includes DST execution units 3-4, and the location 3 includes DST execution units 5-6.

The plurality of locations are established at different distances from the DST processing unit 16 such that messages sent by the DST processing unit 16, via the network 24, arrive at different times at the different locations. For instance, messages sent from the DST processing unit 16 via the network 24 to the DST execution units at the location 1 incur a 20 ms delay, messages sent from the DST processing unit 16 via the network 24 to the DST execution units at the location 2 incur a 30 ms delay, and messages sent from the DST processing unit 16 via the network 24 to the DST execution units at the location 3 incur a 40 ms delay.

The DSN is operable to store data as sets of encoded data slices in the DST execution unit set. In an example of operation of the storing of the data, the DST processing unit 16 receives a store data request 536, where the store data request 536 includes one or more of a data object, a data object name, and a requester identifier (ID). Having received the store data request 536, the DST client module 34 identifies the DST execution unit set that is associated with the store data request 536. The identifying includes at least one of performing a vault lookup based on the requester ID, performing a random selection, and selecting based on available storage capacity.

Having identified the DST execution unit set, the DST client module 34 dispersed storage error encodes the data object to produce a plurality of sets of encoded data slices. Having generated the encoded data slices, the DST client module 34 generates one or more sets of write slice requests that includes the one or more sets of encoded data slices of the plurality of sets of encoded data slices.

For each set of write slice requests, the DST client module 34 determines a transmission schedule such that the set of write slice requests arrives at the plurality of locations at substantially the same timeframe. For example, the DST client module 34 obtains estimated transmission times to each DST execution unit, identifies a long as transmission time, and establishes a time delay for each DST execution unit as a difference between the long as transmission time and the estimated transmission time associated with the DST execution unit, where the delay time is an amount of time to wait before sending the right slice request to the DST execution unit after sending a first write slice request to a DST execution unit associated with the long as transmission time.

Having determined the transmission schedule for each read slice request, a DST client module 34 sends, via the network 24, each write slice request in accordance with the transmission schedule. For example, the DST client module 34 sends, at a beginning time zero, write slice requests 5-6 to DST execution units 5-6 at location 3, sends, at a time 1 (e.g., first time delay), write slice requests 3-4 to the DST execution units 3-4 at location 2, and sends, at a time 2, write slice requests 1-2 to the DST execution units 1-2 and location 1.

Having sent the write slice requests, the DST client module 34 receives write slice responses as write responses 538 from at least some of the DST execution units. The DST client module 34 processes the store data request based on the received write slice responses. For example, the DST client module 34 indicates successful storage when receiving a write threshold number of favorable write slice responses within a time frame. As another example, the DST client module 34 retries the writing process when not receiving the write threshold number of favorable write slice responses within the timeframe (e.g., another DST client module 34 has temporarily locked slice names of the writing process in a write conflict scenario).

FIG. 13B is a flowchart illustrating another example of storing data, which include similar steps as FIG. 44B. The method begins with step 500 of FIG. 44B where a processing module (e.g., of a distributed storage and task (DST) client module) receives a store data request that includes a data object. The method continues at step 542 where the processing module identifies a set of storage units associated with the store data request. The identifying includes at least one of interpreting a vault lookup based on a requester identifier, performing a random selection, performing a selection based on available storage capacity, performing a selection based on performance, and performing a selection based on transmission time delays to each storage unit of the set of storage units.

The method continues at step 544 where the processing module dispersed storage error encodes the data object to produce a plurality of sets of encoded data slices. The processing module may further generate a plurality of sets of slice names corresponding to the plurality of sets of encoded data slices. The method continues at step 546 where the processing module generates one or more sets of write slice requests that include one or more sets of encoded data slices. For example, the processing module generates a write slice request for each storage unit of the set of storage units, where each read slice request includes encoded data slices associated with the storage unit and slice names associated with the encoded data slices.

For each set of write slice requests, the method continues at step 548 where the processing module determines a transmission schedule for each write slice request such that the set of write slice requests arrives at corresponding storage units at substantially the same timeframe. For example, for each storage unit, the processing module obtains an estimated transmission time (e.g., a lookup, initiating a test, interpreting test results), identifies a longest transmission time, and establishes a time delay for each storage unit as a difference between the longest transmission time and the estimated transmission time of the storage unit.

The method continues at step 550 where the processing module sends each write slice request in accordance with the transmission schedule. For example, the processing module sends a write slice request associated with a storage unit of the longest transmission time first, and initiates timing such that the processing module sends success of write slice requests based on the time delays of the transmission schedule. Alternatively, or in addition to, upon detecting a storage failure (e.g., when a timeframe elapses without receiving a read threshold number of favorable write slice responses), the processing module recalculates the transmission scheduled to vary the delay times and we sends write slice requests in accordance with the varied delay times.

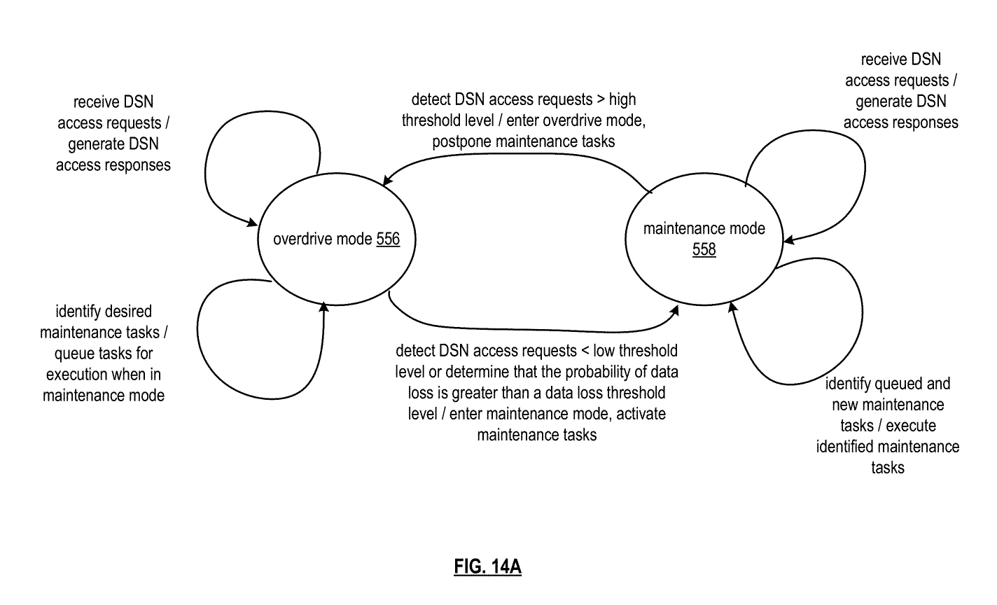

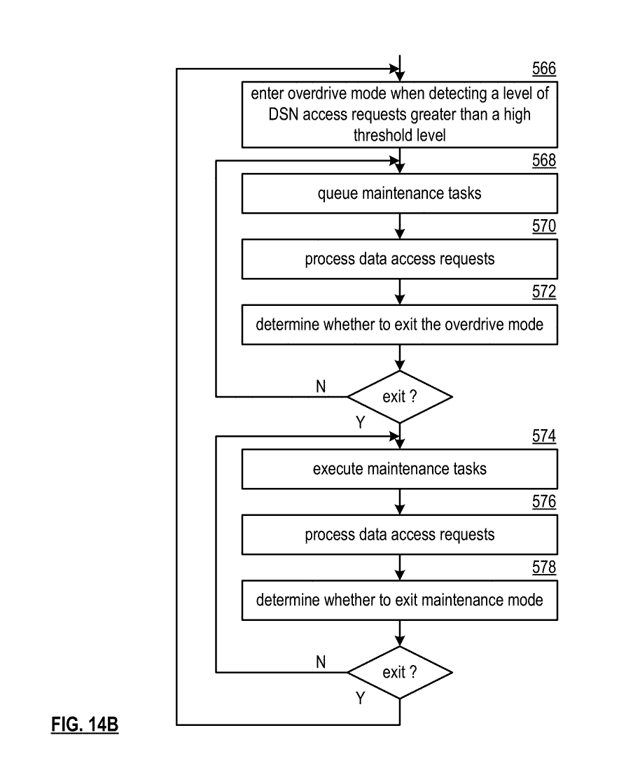

FIG. 14A is a state transition diagram of modes of operation of a dispersed storage network (DSN) that includes two states, an overdrive mode state 556 and a maintenance mode state 558. While operating in the maintenance mode 558, the DSN processes both data access tasks and maintenance tasks. The maintenance tasks include one or more of rebuilding, migration, disk balancing, recording statistics, recording debugging information, and other non-essential data access performance-degrading operations. The data access tasks includes one or more of storing data, retrieving data, deleting data, and listing store data. For example, one or more processing modules of the DSN identifies queued and new maintenance tasks and executes the identified maintenance tasks while in the maintenance mode. As another example, the one or more processing modules of the DSN receives DSN access requests and generates DSN access responses.

While operating in the overdrive mode 556, the DSN processes the data access requests but holds the maintenance tasks. As such, a backlog of further maintenance tasks may grow in size while the DSN is in the overdrive mode. For example, the one or more processing modules of the DSN receives DSN access requests and generates DSN access responses. As another example, the one or more processing modules of the DSN identifies desired maintenance tasks and queues the tasks for execution when the DSN returns to the maintenance mode.

The DSN may transition back and forth between the overdrive mode 556 and the maintenance mode 558 from time to time based on one or more of a level of data access requests (e.g., store data request per unit time, retrieve data request per unit of time) and a probability of data loss (e.g., probability of unrecoverable data when less than a decode threshold number of encoded data slices per set of encoded data slices is available as a result of deferring rebuilding operations etc). As a specific example, while in the maintenance mode 558, the one or more processing modules transitions the DSN from the maintenance mode 558 to the overdrive mode 556 and postpones maintenance tasks when detecting that a level of DSN access requests is greater than a high threshold level. As another specific example, while in the overdrive mode 556, the one or more processing modules transitions the DSN from the overdrive mode 556 to the maintenance mode 558 and activates maintenance tasks when detecting that the level of DSN access requests is less than a low threshold level. As yet another specific example, while in the overdrive mode 556, and the one or more processing modules transitions the DSN from the overdrive mode 556 to the maintenance mode 558 and activates maintenance tasks when determining that the probability of data loss is greater than a data loss threshold level. For instance, the one or more processing modules detects that memory devices are almost full due to lack of rebalancing operations. In another instance, the one or more processing modules detects that a number of available slices per set of encoded data slices is less than a low threshold level due to postponement of rebuilding operations.

FIG. 14B is a flowchart illustrating an example of determining a mode of operation of a dispersed storage network (DSN). The method begins or continues at step 566 where a processing module (e.g., of a distributed storage and task (DST) client module) causes the DSN to enter an overdrive mode when detecting a level of DSN access requests are greater than a high threshold level. The method continues at step 568 where the processing module queues maintenance tasks. For instance, the processing module receives a new maintenance task request and enters the maintenance task request in a dispersed hierarchical index serving as a queue for maintenance tasks.

The method continues at step 570 where the processing module processes data access request. For example, the processing module prioritizes writing new data DSN memory ahead of reading data from the DSN memory. The method continues at step 572 where the processing module determines whether to accept the overdrive mode. For example, the processing module indicates to exit when detecting that the level of DSN access requests is less than a low threshold level. As another example, the processing module indicates to exit when detecting that a probability of data loss is greater than a data loss threshold level. The method loops back to step 568 when the processing module determines not to exit the overdrive mode. The method continues to step 574 when the processing module determines to exit the overdrive mode.

The method continues at step 574 where the processing module executes maintenance tasks. For example, the processing module retrieves queued maintenance tasks from the maintenance task queue and executes the maintenance tasks. The method continues at step 576 where the processing module processes data access requests. For example, the processing module prioritizes the writing of data and the reading of data equally (e.g., first in first out prioritization).

The method continues at step 578 where the processing module determines whether to exit the maintenance mode. For example, the processing module indicates to exit when detecting that the level of data access requests is greater than a high threshold level. The method loops back to step 574 when the processing module determines not to exit the maintenance mode. The method loops back to step 566 when the processing module determines to exit the maintenance mode.

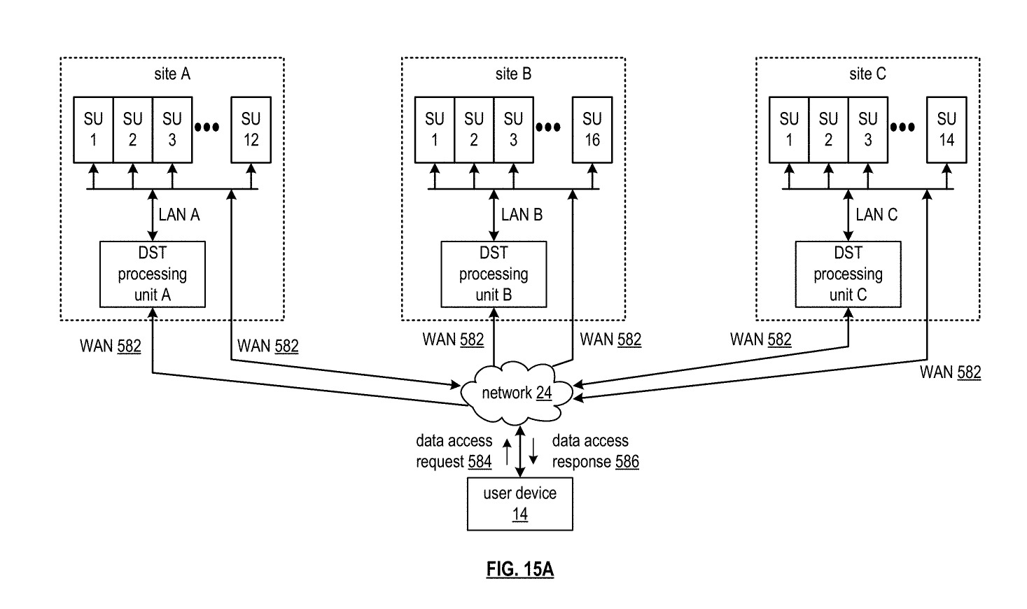

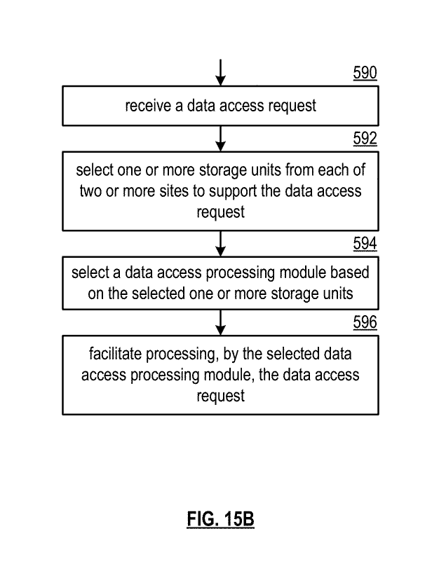

FIG. 15A is a schematic block diagram of another embodiment of a dispersed storage network (DSN) that includes three sites A-C, the network 24 of FIG. 1, and the user device 14 of FIG. 1. Each site includes a plurality of storage units, a local area network (LAN), and a distributed storage and task (DST) processing unit. A number of storage units per site may vary. For example site A includes 12 storage units, site B include 16 storage units, and site C includes 14 storage units. Each storage unit may be implemented utilizing the DST execution (EX) unit 36 of FIG. 1. Each DST processing unit may be implemented utilizing the DST processing unit 16 of FIG. 1. Each site is operably connected to the network 24 via a wide area network (WAN) 582.

The DSN is operable to enable the user device 14 to access data stored as sets of encoded data slices in storage units of the plurality of sites. In an example of operation of accessing the data, at least one of the DST processing unit receives, via the network 24, a data access request 584 (e.g., store data request, a retrieve data request) from the user device 14. For instance, DST processing unit A receives the data access request 584. Having received the data access request 584, the DST processing unit selects a number of storage units at each site to support the data access request 584. For example, the DST processing unit selects the number of storage units based on one or more of storage unit availability, storage unit performance levels, a predetermination, and interpreting a system registry. For instance, the DST processing unit selects all storage units at all sites (e.g., 12 storage units at site A, 16 storage units at site B, and 14 storage units at site C).

Having selected the number of storage units at each site, the DST processing unit selects a DST processing unit of the plurality of DST processing units to process the data access request further, where the selection is based on the number of storage units at each site to support the data access request. For example, the DST processing unit A selects the DST processing unit B to process the data access request further when the 16 storage units selected at site B is greater than the number of storage units selected at sites A and C. Alternatively, or in addition to, the DST processing unit may select the DST processing unit to process the data access request based on one or more of available DST processing unit processing capacity and expected wide area network traffic through the network 24.

Having selected the DST processing unit to process the data access request further, the selected DST processing unit processes the data access request 584. For example, the DST processing unit B receives the data access request 584 from the DST processing unit A, accesses the storage units 1-16 at the site B via the LAN B, accesses the storage units 1-12 at the site A via the network 24 and WAN messaging, accesses the storage units 1-14 at the site C via the network 24 and the WAN messaging, and issues, via the network 24, a data access response 586 to the user device 14 based on the accessing of the storage units.

FIG. 15B is a flowchart illustrating an example of accessing data in a dispersed storage network (DSN). The method begins or continues at step 590 where a processing module (e.g., of a receiving distributed storage and task (DST) processing unit) receives a data access request. The data access request may be received by any one of a plurality of processing modules of the DSN. The data access request may include one or more of a store data request with a data object and a retrieve data request.

The method continues at step 592 where the processing module selects one or more storage units from each of two or more sites of the DSN to support the data access request. The selecting may be based on one or more of storage unit availability, storage unit performance levels, a predetermination, and interpreting a system registry. For example, the processing module selects the storage units based on a system registry lookup, where a portion of the system registry is accessed based on a requesting entity identifier associated with the data access request.

The method continues at step 594 where the processing module selects a data access processing module based on the selected one or more storage units. For example, the processing module selects a data access module associated with a highest number of storage units of the selected one or more storage units at a common site. The method continues at step 596 where the selected data access processing module facilitates processing the data access request. For example, the processing module transfers the data access request to the data access processing module when the selected data access processing module does not possess the data access request, the selected data access processing module issues slice access requests to local storage units and remote storage units, the selected data access processing module receives slice access responses, and the selected data access processing module issues a data access response based on the received slice access responses.

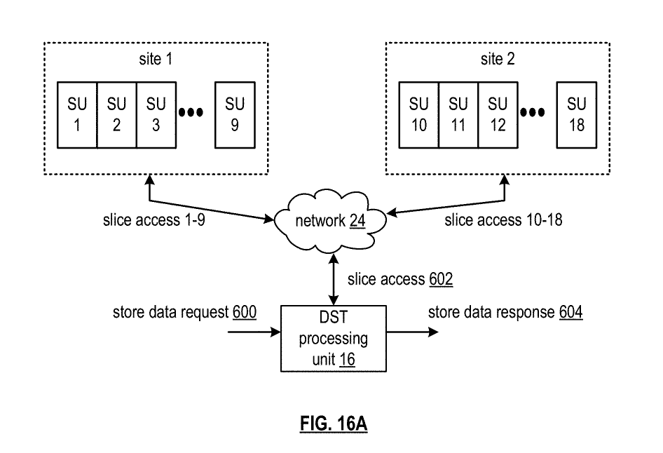

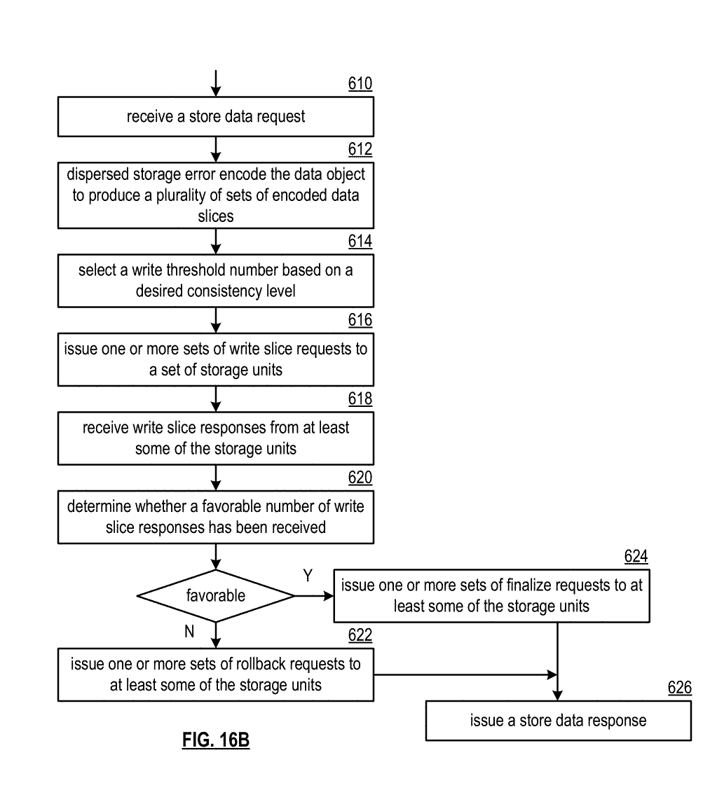

FIG. 16A is a schematic block diagram of another embodiment of a dispersed storage network (DSN) that includes sites 1-2, the network 24 of FIG. 1, and the distributed storage and task (DST) processing unit 16 of FIG. 1. Each site includes a plurality of storage units such that at least a decode threshold number of storage units are implemented at each site and an information dispersal algorithm (IDA) width of an IDA utilized to encode data for storage is at least twice the decode threshold number. For instance, each site includes nine storage units when the decode threshold is 8, a read threshold is 8, and the IDA width is 18.

The DSN is operable to store data assets of encoded data slices. In an example of operation of the storing of the data, the DST processing unit 16 receives a store data request 600, where the store data request 600 includes a data object and a desired consistency level. The desired consistency level includes at least one of a strong consistency level and a weak consistency level. A strong consistency level is associated with guaranteeing that a subsequent reader will see a latest revision of the data when a strong write threshold plus the read threshold is greater than the IDA width. As such, subsequent reads and writes are forced overlap which may expose conflicting revisions while exposing the latest revision.

Having received the store data request 600, the DST processing unit 16 dispersed storage error encodes the data object to produce a plurality of sets of encoded data slices, where each set includes an IDA width number of encoded data slices, and where at least a decode threshold number of encoded data slices per set are required to reconstruct the data object. Having produced the encoded data slices, the DST processing unit 16 selects a write threshold number based on one or more of the desired consistency level, interpreting a system registry value, and storage unit performance levels. For example, the DST processing unit 16 selects a write threshold of 11, such that 11 plus 8>18, when the strong write threshold is required to support the strong consistency level. As another example, the DST processing unit 16 selects a write threshold of 9 when the weak write threshold is required (9+8 is not greater than 18).

Having selected the read threshold number, the DST processing unit 16 issues one or more sets of write slice requests as slice access 602 to the storage units, where the write slice requests includes the plurality of sets of encoded data slices. The DST processing unit 16 receives write slice responses as further slice access 602 from at least some of the storage units. Having received the write slice responses, the DST processing unit 16 determines whether a favorable number of write slice responses have been received within a time frame. For example, the DST processing unit 16 indicates a favorable number of write slice responses when the strong write threshold number of write slice responses have been received. As another example, the DST processing unit 16 indicates that the favorable number of write slice responses has not been received when the strong write threshold number of write slice responses has not been received and the write threshold is the strong write threshold number. As yet another example, the DST processing unit 16 indicates that the favorable number of write slice responses has been received when the week write threshold number of write slice responses has been received and the write threshold number includes the weak write threshold number.

When the favorable number has not been received, the DST processing unit 16 issues one or more sets of rollback requests as further slice access 602 to at least some of the storage units to rollback initiation of storing of the data object. When the favorable number has been received, the DST processing unit 16 issues one or more sets of finalize requests as still further slice access 602 to the at least some of the storage units to complete the storing of the data object. Having sent either of the rollback requests or the finalize requests to the least some of the storage units, the DST processing unit 16 issues a store data response 604 to a requesting entity, where the store data response 604 includes a status associated with storage of the data object. For example, the status indicates which level of consistency was met when the data object was stored.

FIG. 16B is a flowchart illustrating another example of storing data. The method begins or continues at step 610 where a processing module (e.g., of a distributed storage and task (DST) processing unit) receives a store data request. The store data request may include one or more of a data object and a desired consistency level indicator. The method continues at step 612 where the processing module dispersed storage error encodes the data object to produce a plurality of sets of encoded data slices.

The method continues at step 614 where the processing module selects a write threshold number based on a desired consistency level. Alternatively, or in addition to, the processing module establishes the write threshold number based on one or more of the desired consistency level, a system registry value, and storage unit performance levels.

The method continues at step 616 where the processing module issues one or more sets of write slice requests to a set of storage units, where the one or more sets of write slice requests includes the plurality of sets of encoded data slices. The method continues at step 618 where the processing module receives write slice responses from at least some of the storage units. The write slice responses indicates a status of writing individuals slices to individual storage units, where the status includes at least one of successfully stored or error.

The method continues at step 620 where the processing module determines whether a favorable number of write slice responses has been received. For example, the processing module indicates favorable when at least the write threshold number of write slice responses has then received within a time frame. The method branches to step 624 when the favorable number of write slice responses has been received. The method continues to step 622 when the favorable number of write slice responses has not been received.

The method continues at step 622 where the processing module issues one or more sets of rollback requests to at least some of the storage units when the favorable number of write slice responses has not been received. The method branches to step 626 where the processing module issues a store data response. The method continues at step 624 where the processing module issues one or more sets of finalize requests to at least some of the storage units when the favorable number of write slice responses has been received. The method branches to step 626. The method continues at step 626 where the processing module issues a store data response. The issuing includes generating the store data response to include an indicator that indicates which level of consistency has been met.

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “operably coupled to”, “coupled to”, and/or “coupling” includes direct coupling between items and/or indirect coupling between items via an intervening item (e.g., an item includes, but is not limited to, a component, an element, a circuit, and/or a module) where, for indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “operable to” or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item. As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

As may also be used herein, the terms “processing module”, “processing circuit”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the Figures. Such a memory device or memory element can be included in an article of manufacture.

The present invention has been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention. One of average skill in the art will also recognize that the functional building blocks, and other illustrative blocks, modules and components herein, can be implemented as illustrated or by discrete components, application specific integrated circuits, processors executing appropriate software and the like or any combination thereof.

The present invention may have also been described, at least in part, in terms of one or more embodiments. An embodiment of the present invention is used herein to illustrate the present invention, an aspect thereof, a feature thereof, a concept thereof, and/or an example thereof. A physical embodiment of an apparatus, an article of manufacture, a machine, and/or of a process that embodies the present invention may include one or more of the aspects, features, concepts, examples, etc., described with reference to one or more of the embodiments discussed herein. Further, from figure to figure, the embodiments may incorporate the same or similarly named functions, steps, modules, etc., that may use the same or different reference numbers and, as such, the functions, steps, modules, etc., may be the same or similar functions, steps, modules, etc., or different ones.

While the transistors in the above described figure(s) is/are shown as field effect transistors (FETs), as one of ordinary skill in the art will appreciate, the transistors may be implemented using any type of transistor structure including, but not limited to, bipolar, metal oxide semiconductor field effect transistors (MOSFET), N-well transistors, P-well transistors, enhancement mode, depletion mode, and zero voltage threshold (VT) transistors.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of the various embodiments of the present invention. A module includes a processing module, a functional block, hardware, and/or software stored on memory for performing one or more functions as may be described herein. Note that, if the module is implemented via hardware, the hardware may operate independently and/or in conjunction software and/or firmware. As used herein, a module may contain one or more sub-modules, each of which may be one or more modules.

While particular combinations of various functions and features of the present invention have been expressly described herein, other combinations of these features and functions are likewise possible. The present invention is not limited by the particular examples disclosed herein and expressly incorporates these other combinations.

What is claimed is:

1. A method for execution by one or more processing modules of one or more computing devices of a dispersed storage network (DSN), the method comprises:
receiving, by the one or more processing modules, an access request for a set of encoded data slices (EDSs), wherein a data segment is encoded using an error coding dispersal storage function to produce the set of EDSs,
determining, by the one or more processing modules, whether a level of access requests for the DSN meets a predetermined threshold;
in response to determining that the level of access requests for the DSN meets the predetermined threshold, transitioning, by the one or more processing modules, from a first operational mode to a second operational mode;
determining, by the one or more processing modules, whether the level of access requests for the DSN is below the predetermined threshold; and
in response to determining that the level of access requests for the DSN is below the predetermined threshold, transitioning, by the one or more processing modules, from the second operational mode to the first operational mode.

2. The method of claim 1, wherein the first operational mode involves processing of access requests for EDSs and processing of one or more maintenance functions.

3. The method of claim 2, wherein the maintenance functions include at least one of rebuilding EDSs, migrating EDSs, balancing data load across memory devices, recording DSN statistics, and recording DSN debugging information.

4. The method of claim 2, wherein the maintenance functions include one or more functions that degrade performance of one or more access requests.

5. The method of claim 1, wherein the predetermined threshold is at least partially based on a probability of data loss, and further wherein the second operational mode has a higher probability of data loss than the first operational mode.

6. The method of claim 1, wherein the second operational mode includes processing of access requests for EDSs and queueing at least one maintenance function.

7. The method of claim 1, further comprising:
determining, by the one or more processing modules, whether a probability of data loss is above another predetermined threshold; and
in response to a determination that a probability of data loss is above another predetermined threshold, transitioning, by the one or more processing modules, from the second operational mode to the first operational mode.

8. The method of claim 7, wherein the probability of data loss is based on another probability that the DSN includes unrecoverable EDSs when less than a decode threshold number of EDSs of the set of EDSs is available.

9. The method of claim 1, wherein the level of access requests includes at least one of number of access requests for EDSs, a unit time to store requests for EDSs, and a unit time to retrieve requests for EDSs.

10. The method of claim 1, further comprising:
determining, by the one or more processing modules, whether one or more memory devices of the DSN is above predetermined storage threshold; and
in response to determining that the one or more memory devices of the DSN is above the predetermined storage threshold; transitioning, by the one or more processing modules, from the second operational mode to the first operational mode.

11. A computer readable storage medium comprises:
at least one memory section that stores operational instructions that, when executed by one or more processing resources of a plurality of processing resources of one or more computing devices of a distributed network, causes the one or more computing devices to:
receive, by the plurality of processing resources, an access request for a set of encoded data slices (EDSs), wherein a data segment is encoded using an error coding dispersal storage function to produce the set of EDSs,
determine, by the plurality of processing resources, whether a level of access requests for the DSN meets a predetermined threshold;
when the level of access for the DSN meets a predetermined threshold, transitioning, by the plurality of processing resources, from a first operational mode to a second operational mode;
determine, by the plurality of processing resources, whether the level of access requests for the DSN is below the predetermined threshold; and
when the level of access requests for the DSN is below the predetermined threshold, transition, by the plurality of processing resources, from the second operational mode to the first operational mode.

12. The computer readable storage medium of claim 11, wherein the first operational mode involves processing of access requests for EDSs and processing of one or more maintenance functions.

13. The computer readable storage medium of claim 12, wherein the maintenance functions include at least one of rebuilding EDSs, migrating EDSs, balancing data load across memory devices, recording DSN statistics, and recording DSN debugging information.

14. The computer readable storage medium of claim 12, wherein the maintenance functions include one or more functions that degrade performance of one or more access requests.

15. The computer readable storage medium of claim 11, wherein the predetermined threshold is at least partially based on a probability of data loss, and further wherein the second operational mode has a higher probability of data loss than the first operational mode.

16. The computer readable storage medium of claim 11, wherein the second operational mode includes processing of access requests for EDSs and queueing at least one maintenance function.

17. The computer readable storage medium of claim 11, wherein the level of access requests includes at least one of number of access requests for EDSs, a unit time to store requests for EDSs, and a unit time to retrieve requests for EDSs.

18. The computer readable storage medium of claim 11, wherein the plurality of processing resources further causes the one or more computing devices to:
determine, whether one or more memory devices of the DSN is above predetermined storage threshold; and
when the one or more memory devices of the DSN is above the predetermined storage threshold; transition from the second operational mode to the first operational mode.

19. A computing device of a group of computing devices of a distributed network, the computing device comprises:
an interface;
a local memory; and
a processing resource of a plurality of processing resources of the distributed network, wherein the processing resource is operably coupled to the interface and the local memory, and wherein the processing resource functions to:
receive an access request for a set of encoded data slices (EDSs), wherein a data segment is encoded using an error coding dispersal storage function to produce the set of EDSs,
determine whether a level of access requests for the DSN meets a predetermined threshold;
when the level of access for the DSN meets a predetermined threshold, transition from a first operational mode to a second operational mode;
determine whether the level of access requests for the DSN is below the predetermined threshold; and
when the level of access requests for the DSN is below the predetermined threshold, transition from the second operational mode to the first operational mode.

20. The computing device of claim 19, wherein the second operational mode includes access request processing and maintenance function queueing.
